(19) United States
(12) Patent Application Publication
(10) Pub. No.: US 2025/0069882 A1
(43) Pub. Date: Feb. 27, 2025

(54) SILICON NITRIDE DEPOSITION

(71) Applicant: Lam Research Corporation, Fremont, CA (US)

(72) Inventors: Awnish Gupta, Hillsboro, OR (US); Bart J. Van Schravendijk, Palo Alto, CA (US); Jon Henri, West Linn, OR (US); Oksana Savchak, Tualatin, OR (US); Fengyan Wei, Meridian, ID (US); Easwar Srinivasan, Portland, OR (US)

(21) Appl. No.: 18/727,030

(22) PCT Filed: Dec. 30, 2022
(86) PCT No.: PCT/US2022/082624

§ 371 Date: Jul. 5, 2024

Related U.S. Application Data
(60) Provisional application No. 63/266,552, filed on Jan. 7, 2022.

(51) Int. Cl. H01L 21/02; C23C 16/34; C23C 16/455

(52) U.S. Cl. CPC H01L 21/0217; C23C 16/345; C23C 16/45527; C23C 16/45553; H01L 21/02211; H01L 21/0228

(57) ABSTRACT

Methods and apparatuses for depositing silicon nitride in various applications are provided. Embodiments include depositing silicon nitride directly on silicon or silicon oxide surfaces using modulated dose to conversion time ratios in thermal atomic layer deposition. Embodiments include exposing a silicon oxide surface to a nitrogen-containing plasma treatment prior to depositing any silicon nitride and depositing silicon nitride by thermal atomic layer deposition.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor device fabrication may involve deposition of silicon nitride films. Silicon nitride thin films have unique physical, chemical, and mechanical properties and thus are used in a variety of applications. For example, silicon nitride films may be used in diffusion barriers, gate insulators, sidewall spacers, encapsulation layers, strained films in transistors, and the like.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect involves a method for processing substrates, the method including: providing a semiconductor substrate having an exposed surface to a process chamber; performing a pre-treatment on the semiconductor substrate by either (1) heating the semiconductor substrate to a first temperature and/or (2) exposing the semiconductor substrate to a nitrogen-containing plasma; introducing flow of a halosilane gas to the process chamber using a dose time; after stopping flow of the halosilane gas, purging the process chamber for a first purge time; introducing flow of a first nitrogen-containing gas to the process chamber using a conversion time to form silicon nitride by thermal atomic layer deposition; and after stopping flow of the first nitrogen-containing gas, purging the process chamber for a second purge time.

In various embodiments, the exposed surface includes silicon oxide.

In various embodiments, the nitrogen-containing plasma is formed by igniting a second nitrogen-containing gas. For example, the second nitrogen-containing gas may be any one of nitrogen, ammonia, nitrous oxide, and combinations thereof.

In various embodiments, the first temperature is less than about 800° C.

In various embodiments, the first temperature and the second temperature are the same.

In various embodiments, the halosilane gas includes chlorine.

Another aspect involves a method for processing substrates, the method including: providing a semiconductor substrate having an exposed surface to a process chamber; heating the semiconductor substrate to a first temperature; performing a pre-treatment on the semiconductor substrate by exposing the semiconductor substrate to a nitrogen-containing plasma; after performing the pre-treatment, heating the semiconductor substrate to a second temperature; after heating the semiconductor substrate to the second temperature, introducing flow of a halosilane gas to the process chamber in a plasma-free environment using a dose time; after stopping flow of the halosilane gas, purging the process chamber for a first purge time; introducing flow of a first nitrogen-containing gas to the process chamber using a conversion time to form silicon nitride in a plasma-free environment; and after stopping flow of the first nitrogen-containing gas, purging the process chamber for a second purge time.

In various embodiments, the exposed surface includes silicon oxide.

In various embodiments, the nitrogen-containing plasma is formed by igniting a second nitrogen-containing gas. For example, the second nitrogen-containing gas may be any one of nitrogen, ammonia, nitrous oxide, and combinations thereof.

In various embodiments, the first temperature is less than about 800° C.

In various embodiments, the first temperature and the second temperature are the same.

In various embodiments, the halosilane gas includes chlorine.

Another aspect involves a method for processing substrates, the method including: providing a semiconductor substrate having an exposed surface to a process chamber; exposing the exposed surface to a nitrogen-containing plasma; introducing flow of a silicon-containing gas to the process chamber using a dose time; after stopping flow of the silicon-containing gas, purging the process chamber for a first purge time; introducing flow of a first nitrogen-containing gas to the process chamber using a conversion time to form silicon nitride by thermal atomic layer deposition; and after stopping flow of the first nitrogen-containing gas, purging the process chamber for a second purge time, whereby a ratio of the dose time to conversion time is about 1:1 to about 10:4.

In various embodiments, the silicon nitride has an atomic ratio of silicon to nitrogen of at least about 0.69.

In various embodiments, the silicon nitride has an atomic ratio of silicon to nitrogen of at least about 1.

In various embodiments, the silicon-containing gas includes chlorine.

In various embodiments, the silicon-containing gas is a halosilane.

In various embodiments, the exposed surface includes silicon. In some embodiments, the exposed surface further includes oxygen.

Another aspect involves a method for processing substrates, the method: providing a semiconductor substrate having an exposed surface to a process chamber; exposing the exposed surface to a nitrogen-containing plasma; introducing flow of a silicon-containing gas to the process chamber in a plasma-free environment using a dose time; after stopping flow of the silicon-containing gas, purging the process chamber for a first purge time; introducing flow of a first nitrogen-containing gas to the process chamber using a conversion time to form silicon nitride in a plasma-free environment; and after stopping flow of the first nitrogen-containing gas, purging the process chamber for a second purge time, whereby a ratio of the dose time to conversion time is about 1x:3x to about 10x:12x where x is about 0.2 second to about 10 seconds.

In various embodiments, the silicon nitride has an atomic ratio of silicon to nitrogen of at least about 0.69.

In various embodiments, the silicon nitride has an atomic ratio of silicon to nitrogen of at least about 1.

In various embodiments, the silicon-containing gas includes chlorine.

In various embodiments, the silicon-containing gas is a halosilane.

In various embodiments, the exposed surface includes silicon. In some embodiments, the exposed surface further includes oxygen.

Another aspect involves an apparatus for processing substrates, the apparatus including: one or more process chambers, each process chamber including a chuck; one or more gas inlets into the process chambers and associated flow-control hardware; and a controller having at least one processor and a memory, whereby the at least one processor and the memory are communicatively connected with one another, the at least one processor is at least operatively connected with the flow-control hardware, and the memory stores computer-executable instructions for controlling the at least one processor to at least control the flow-control hardware to: cause a substrate to be provided to one of the one or more process chambers; cause a plasma to be generated using a nitrogen-containing gas to generate a nitrogen plasma species; cause the substrate to be exposed to the nitrogen plasma species in the one or more process chambers; cause introduction of a silicon-containing precursor to the one or more process chambers; and cause introduction of a nitrogen-containing reactant to convert the silicon-containing precursor to silicon nitride in a plasma-free environment.

Another aspect involves an apparatus for processing substrates, the apparatus including: one or more process chambers, each process chamber including a chuck; one or more gas inlets into the process chambers and associated flow-control hardware; and a controller having at least one processor and a memory, whereby the at least one processor and the memory are communicatively connected with one another, the at least one processor is at least operatively connected with the flow-control hardware, and the memory stores computer-executable instructions for controlling the at least one processor to at least control the flow-control hardware to: cause a substrate to be provided to one of the one or more process chambers; cause introduction of a halosilane precursor to the one or more process chambers for a dose time; and cause introduction of a nitrogen-containing reactant for a conversion time to convert the halosilane precursor to silicon nitride in a plasma-free environment, whereby a ratio of dose time to conversion time of about 1x:3x to about 10x:12x where x is about 0.2 second to about 10 seconds, is used.

These and other aspects are described further below with reference to the drawings.

### BRIEF DESCRIPTION OF THE DRAWINGS

FIG. 1A is a process flow diagram depicting operations that are performed in accordance with certain disclosed embodiments.

FIG. 1B is a process flow diagram depicting operations that are performed in accordance with certain disclosed embodiments.

FIG. 2 is a timing schematic diagram depicting gas flows and plasma on and off phases for various operations that may be performed in accordance with certain disclosed embodiments.

FIG. 3 is a schematic diagram of an example process chamber for performing certain disclosed embodiments.

FIG. 4 is a schematic diagram of an example process tool for performing certain disclosed embodiments.

FIG. 5 is a graph of experimental results showing growth per cycle rates for silicon nitride deposition on various substrates.

FIG. 6 is a graph of experimental results showing relative nitrogen content for silicon nitride films deposited on oxide and silicon substrates.

FIG. 7 is a graph of experimental results showing growth per cycle rates for silicon nitride deposition on various substrates.

FIG. 8 is a graph of experimental results showing sidewall growth per cycle rates with respect to various depths of features in various substrates.

FIGS. 9A and 9B depict silicon content of silicon nitride films.

FIGS. 10A and 10B show graphs of experimental results showing sidewall thickness of silicon nitride films deposited in features of substrates relative to the feature depth.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes involve deposition of silicon nitride. Certain fabrication processes may involve forming silicon nitride on and in various structures. Structures may have varying topography and compositions and it may be challenging to deposit silicon nitride into or onto such structures. For example, silicon nitride may be difficult to deposit on silicon oxide surfaces, silicon nitride may be difficult to deposit into high aspect ratio features, and some applications may utilize silicon nitride with variable Si:N atomic ratios. While certain methods may be used for depositing silicon nitride generally, such methods have disadvantages such as use of extremely high temperatures, longer process times, reduced tunability windows, and increased nucleation delay.

Provided herein are methods of depositing silicon nitride using a pre-treatment involving either nitrogen-containing plasma or heat treatment prior to depositing silicon nitride by thermal atomic layer deposition (ALD) using tunable process conditions including relative dose and conversion times during ALD to achieve a variety of advantageous features, including, but not limited to, conformality in high aspect ratio features, silicon-rich silicon nitride films, and reduced nucleation delay.

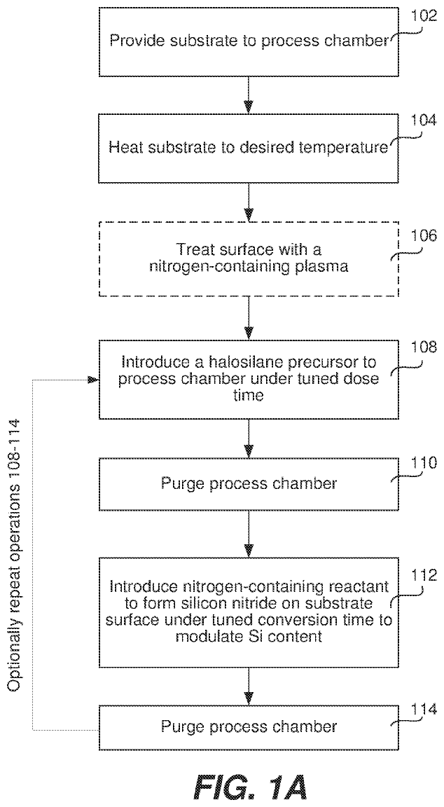

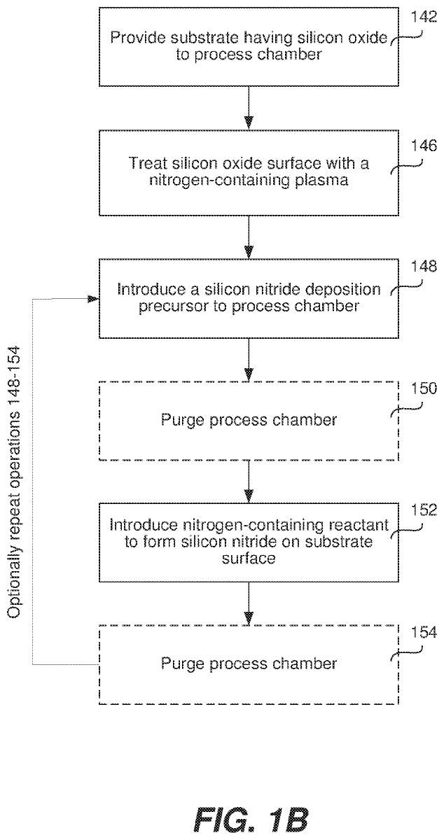

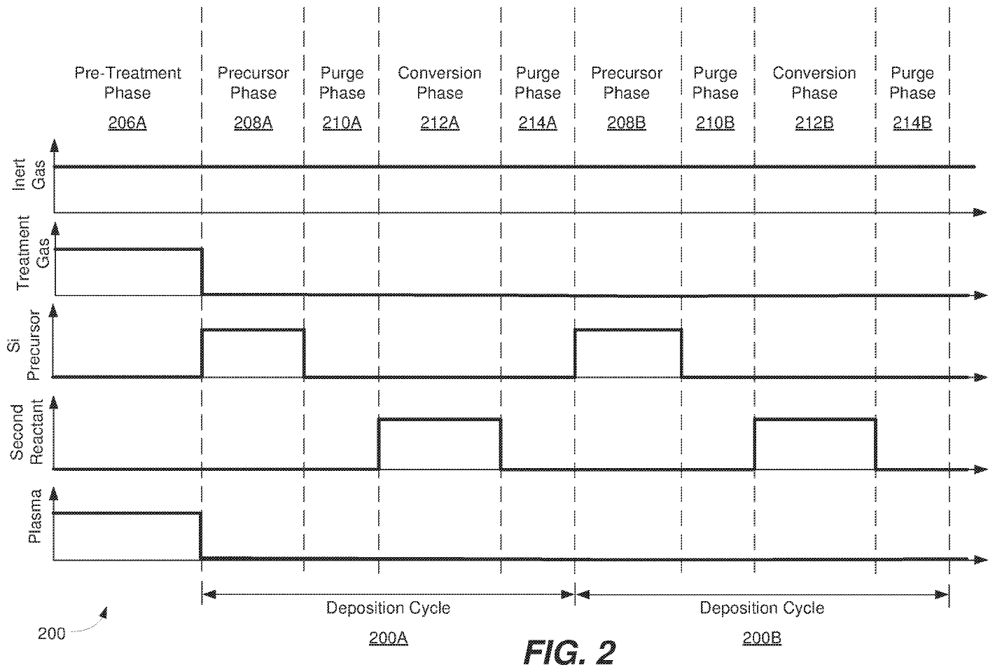

FIGS. 1A and 1B are process flow diagrams depicting operations that may be performed in methods in accordance with certain disclosed embodiments. A further example is described below with respect to the timing schematic in FIG. 2. Note that while FIG. 2 shows a particular sequence of operations performed in one embodiment, other variations that include or exclude plasma treatment, include or exclude heat treatment, and include or exclude modulation of dose, conversion, and purge times, may be performed depending on desired characteristics of deposited silicon nitride.

Certain disclosed embodiments are directed to ALD processes. ALD is a technique that deposits thin layers of material using sequential self-limiting reactions. Typically, an ALD cycle includes operations to deliver and adsorb at least one reactant to the substrate surface, and then react the adsorbed reactant with one or more reactants to form the partial layer of film. As an example, a silicon nitride deposition cycle may include the following operations: (i) delivery/adsorption of a silicon-containing precursor, (ii) purging of the silicon precursor from the chamber, (iii) delivery of a nitrogen-containing reactant or nitrogen-containing gas, and (iv) purging of the nitrogen-containing reactant and additional reaction by-products from the chamber.

Unlike a chemical vapor deposition (CVD) technique, ALD processes use surface-mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physisorbed molecules of the first precursor. It should be understood that when the compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the chamber may be evacuated such that the partial pressure of the first precursor in gas phase is sufficiently low to mitigate a reaction. A second reactant, such as a nitrogen-containing reactant, is introduced to the chamber so that some of these molecules react with the first precursor adsorbed on the surface. In some processes, the second reactant reacts immediately with the adsorbed first precursor. The chamber may then be evacuated again to remove unbound second reactant molecules. As described above, in some embodiments, the chamber may not be completely evacuated. Additional ALD cycles may be used to build film thickness.

In certain embodiments, an ALD first precursor dose partially saturates the substrate surface. In some embodiments, the dose phase of an ALD cycle concludes before the precursor contacts the substrate to evenly saturate the surface. Typically, the precursor flow is turned off or diverted at this point, and only purge gas flows. By operating in this sub-saturation regime, the ALD process reduces the cycle time and increases throughput. However, because precursor adsorption is not saturation limited, the adsorbed precursor concentration may vary slightly across the substrate surface. Examples of ALD processes operating in the sub-saturation regime are provided in U.S. patent application Ser. No. 14/061,587 (now U.S. Pat. No. 9,355,839), filed Oct. 23, 2013, titled “SUB-SATURATED ATOMIC LAYER DEPOSITION AND CONFORMAL FILM DEPOSITION,” which is incorporated herein by reference in its entirety.

As described, in some implementations, the ALD methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

In an operation 102 of FIG. 1A, a substrate is provided to a process chamber. The substrate may be a silicon wafer, e.g., a 200-mm wafer, or a 300-mm wafer, including wafers having one or more layers of material, such as dielectric, conducting, or semi-conducting material deposited thereon. Non-limiting examples of under-layers include dielectric layers and conducting layers, e.g., silicon oxides, silicon nitrides, silicon carbides, metal oxides, metal nitrides, metal carbides, and metal layers.

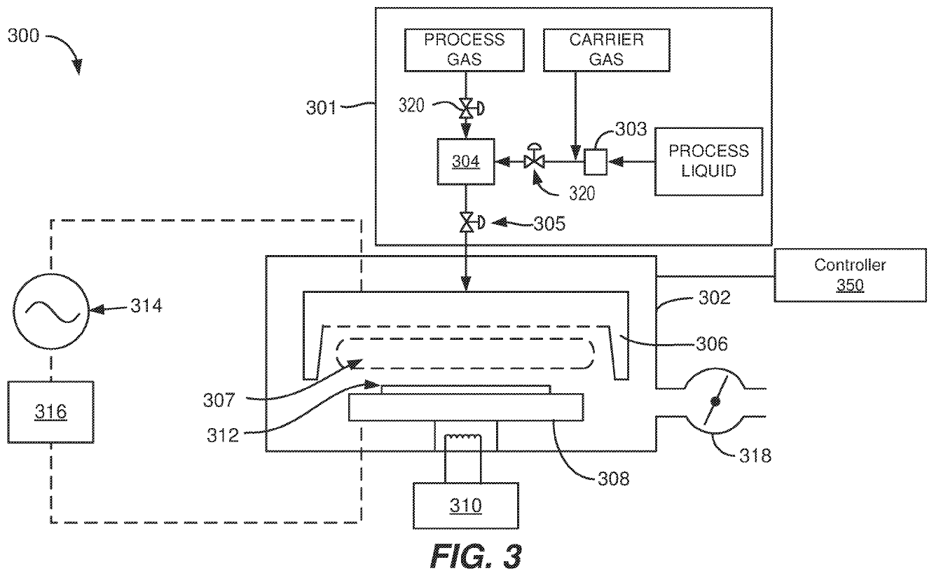

In some embodiments, the process chamber is a single-wafer chamber. In some embodiments, the process chamber is a single-wafer station in a multi-station chamber, such as a 4-station chamber. In some embodiments, the process chamber is a furnace chamber. An example of a process chamber is further described below with respect to FIG. 3.

In some embodiments, operations in FIG. 1A are performed at the same chamber pressure, such as between about 0.5 Torr and about 50 Torr or about 5 Torr to about 25 Torr. In some embodiments, operations in FIG. 1A are performed isobarically. In some embodiments, operations in FIG. 1A are performed in different chambers or at different pressures. In some embodiments, a multi-station chamber is used such that each station is set at a different pressure, and a substrate may be shuttled between stations during processing such that one or more operations are performed in different stations.

In some embodiments, operations in FIG. 1A are performed at different temperatures. In some embodiments, operations in FIG. 1A are performed at the same temperature or isothermally. Example deposition temperatures may be about 500° C. to about 700° C., or less than about 850° C., or less than about 700° C., or less than about 650° C., or about 650° C. Temperature may refer to pedestal temperature or substrate temperature which is understood to be the temperature that the pedestal is set at to heat or cool the substrate to the set temperature. In some embodiments, operations in FIG. 1A are performed in different chambers having different pedestal temperatures or at different temperatures. In some embodiments, a multi-station chamber is used such that each station is set at a different temperature, and a substrate may be shuttled between stations during processing such that one or more operations are performed in different stations.

In an operation 104, the substrate is heated to a desired temperature. In various embodiments, the temperature may be about 500° C. to about 700° C., or less than about 850° C., or less than about 700° C., or less than about 650° C., or about 650° C., or less than about 500° C., or less than about 400° C., or less than about 300° C., or less than about 200° C.

In an operation 106, a surface of the substrate is optionally treated with a nitrogen-containing plasma. In some embodiments, operations 104 and 106 may both be performed. In some embodiments, only one of operations 104 and 106 is performed. In some embodiments, heating the substrate in operation 104 is selected to enable deposition of a silicon-rich film using a halosilane precursor. In some embodiments, treating the substrate in operation 106 may be performed to reduce nucleation delay on the substrate surface. For example, for depositing silicon nitride on a silicon oxide surface, because it may be difficult to nucleate a silicon nitride deposition precursor onto a silicon oxide surface, the silicon oxide surface of the substrate may be treated in operation 106 prior to depositing silicon nitride. In various embodiments, operation 106 may be performed prior to operations 108-114, or after operation 104, or both.

Treatment with a nitrogen-containing plasma in operation 106 may be performed by flowing or introducing a nitrogen-containing plasma species generated or ignited using a nitrogen-containing gas in an upstream location or remote chamber, or by flowing or introducing a nitrogen-containing gas to the chamber and igniting the gas in situ. The nitrogen-containing gas may be any suitable nitrogen-containing gas, such as but not limited to nitrogen, ammonia, deuterated ammonia (ND₃), NH₂D, NHD₂, and combinations thereof. In various embodiments, a gas containing both nitrogen and hydrogen may be used. In various embodiments, a mixture of nitrogen-containing gases may be used, such as but not limited to a mixture of nitrogen and ammonia. The plasma species used to perform treatment may be ion-free. The plasma species used to perform treatment may be radical-based. In various embodiments, the plasma species is passed through a showerhead such that the substrate surface is exposed primarily to radicals. Radicals that may be used for plasma treatment include but are not limited to nitrogen radicals and hydrogen radicals. In some embodiments, the radicals include NH radicals. In some embodiments, the plasma is an inductively coupled plasma. In some embodiments, the plasma is a capacitively coupled plasma. In some embodiments, the plasma is a radical assisted plasma. In some embodiments, the plasma is an ion-free plasma. The more the substrate is exposed to more radicals, the more nucleation delay is reduced for subsequent silicon nitride deposition.

The plasma may be generated using a plasma power of about 500 W to about 10000 W, or about 500 W to about 4000 W, or about 1000 W to about 4000 W, or about 2000 W to about 4000 W for a single-station chamber. The flow rate of the nitrogen-containing gas depends on the nitrogen-containing gas selected and the mixture of gases used. For example, in a mixture of nitrogen gas and ammonia, the percentage of nitrogen gas may be about 0% to about 100% and the percentage of ammonia gas may be about 0% to about 100%, where the sum total of the percentage of nitrogen gas and ammonia gas for the total flow of nitrogen-containing gas is 100%. For example, in one non-limiting example, a 40% nitrogen gas and 60% ammonia gas mixture is used. The relative flow rates of nitrogen gas and ammonia gas may be about 1:10 to about 200:1.

In some embodiments, nitrogen gas may be flowed to a single-station chamber, in a mixture or alone, at a flow rate of about 1 slm to about 50 slm, or about 10 slm to about 30 slm. In some embodiments, ammonia gas may be flowed to a single-station chamber, in a mixture or alone, at a flow rate of about 100 sccm to about 10000 sccm or between about 4000 sccm and about 5000 sccm.

The duration of plasma treatment depends on a variety of factors, including the material to be deposited, the surface to be deposited on, the precursors used for material deposition, and other process conditions. In various embodiments, plasma treatment may be performed for a duration about 30 seconds to about 30 minutes, or about 1 minute to about 30 minutes, or about 10 minutes to about 30 minutes. In various embodiments, operation 106 is performed only once before any silicon nitride is deposited. In some embodiments, operation 106 is performed on an exposed silicon oxide surface one before any silicon nitride is deposited.

In an operation 108, a halosilane precursor is introduced to the process chamber under a tuned dose time. In various embodiments, the halosilane precursor is introduced without a plasma. In various embodiments, the halosilane precursor is introduced to the process chamber in a plasma-free environment.

Operation 108 may be performed in various embodiments for forming silicon-rich films. That is, in some embodiments, using a halosilane precursor in combination with a particular dose time may be used to form silicon-rich films. Example dose times include but are not limited to about 0.1 second to about 100 seconds. The dose time may refer to the duration for which flow of a precursor used during the dose is introduced to the process chamber. For example, the dose time of dichlorosilane may be the duration in which dichlorosilane is introduced to the process chamber.

Any halosilane precursor may be used in operation 108. A halosilane precursor may also be referred to as a halogen-containing silane precursor or a halogen-containing silicon precursor or a halogen-containing silane gas. In some embodiments, a halogen-containing silane may be used such that the silane includes at least one hydrogen atom. Such a silane may have a chemical formula of SiXₐH_{y} where y≥0 where X is a halogen. For example, dichlorosilane (H₂SiCl₂) may be used in some embodiments. In some embodiments, a silane may have a chemical formula of SiₐX_{b}, where a≥0 and b≥0 (i.e., b=a+4). In such embodiments, silanes may include tetrachlorosilane and HCDS.

In some embodiments, a halogen-containing silane precursor may be used such that the silane includes at least one hydrogen atom. Such a silane may have a chemical formula of SiXₐH_{y} where y≥1. In some embodiments, halogen-containing silane may be a dihalosilane, or a trihalosilane, or may include more than three silicon atoms. In some embodiments, For example, dichlorosilane (H₂SiCl₂) may be used in some embodiments. Another example of a chemical formula of a halogen-containing silane is SiₙX_{y}H_{z} where X is a halogen and H is hydrogen; n is an integer greater than or equal to 1 and is equal to the number of Si atoms in the molecule; in some embodiments, y is about 1 to about 4, and z is 4-y. In some embodiments, the halogen-containing silane has a chemical formula of SiₙX_{y}, where n is any integer greater than or equal to 1, and y is 2n+2. Additional examples include but are not limited to SiHCl₃, SiH₂Cl₂, SiH₃Cl, and Si₂Cl₆. Another example of a chemical formula of a halogen-containing silane is SinH₂ₙ₊₁ X where n is an integer greater than or equal to 1 and X is a halogen. Examples of halosilanes are iodosilanes, bromosilanes, chlorosilanes and fluorosilanes. Specific chlorosilanes include but are not limited to tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

In some embodiments, the halosilane is carbon-free. In some embodiments, the halosilane is an organic silicon-containing precursor.

In some embodiments, the halosilane precursor has at least one optionally substituted C₁₋₂ haloalkyl group. Non-limiting haloaliphatic groups include —CX_{y}H_{3-y}, wherein y is 1, 2, or 3, and wherein each X is, independently, halo (F, Cl, Br, or I); —CX_{z}H_{2-z}CX_{y}H_{3-y}, wherein z is 0, 1, or 2, wherein y is 0, 1, 2, or 3, and wherein each X is, independently, halo (F, Cl, Br, or I), in which at least one of z or y is not 0; or —CH₂CX_{y}H_{3-y}, wherein y is 1, 2, or 3, and wherein each X is, independently, halo (F, Cl, Br, or I). Yet other non-limiting haloalkyl groups include fluoromethyl (—CH₂F), difluoromethyl (—CHF₂), trifluoromethyl (—CF₃), chloromethyl (—CH₂Cl), dichloromethyl (—CHCl₂), trichloromethyl (—CCl₃), bromomethyl (—CH₂Br), dibromomethyl (—CHBr₂), tribromomethyl (—CBr₃), iodomethyl (—CH₂I), diiodomethyl (—CHI₂), triiodomethyl (—CI₃), bromofluoromethyl (—CHFBr), chlorofluoromethyl (—CHFCl), fluoroiodomethyl (—CHFI), 2-fluoroethyl (—CH₂CH₂F), 2-chloroethyl (—CH₂CH₂Cl), 2-bromoethyl (—CH₂CH₂Br), 2-iodoethyl (—CH₂CH₂I), 2,2-difluoroethyl (—CH₂CHF₂), 2,2-dichloroethyl (—CH₂CHCl₂), 2,2-dibromoethyl (—CH₂CHBr₂), 2,2-diiodoethyl (—CH₂CHI₂), 2,2-fluoroiodoethyl (—CH₂CHFI), and the like. In particular embodiments, the C₁₋₂ haloalkyl includes β-halo-substituted ethyl. Yet other haloaliphatic groups include C₁₄ haloalkyl, C₂₄ haloalkenyl, and C₂₄ haloalkynyl.

The flow rate of the halosilane depends on the size of the chamber, the chamber pressure, the precursor used, and a variety of other features. In various embodiments, the flow rate of the halosilane for a single-station chamber is about 100 sccm to about 2000 sccm, or about 300 sccm to about 1500 sccm, or about 500 sccm to about 1500 sccm. In some embodiments, nitrogen gas may also be introduced to dilute the precursor. For example, in some embodiments, the flow rate of nitrogen gas for a single-station chamber may be about 1000 sccm to about 40000 sccm or about 500 sccm to about 2000 sccm.

The chamber pressure during operation 106 may be about 1 Torr to about 25 Torr, or about 1 Torr to about 10 Torr, or about 3 Torr to about 10 Torr, or about 5 Torr to about 10 Torr.

Dose time in operation 108 may be modulated to modify properties of the silicon nitride film to be deposited. For example, in some embodiments, to form a silicon-rich silicon nitride film, dose time for operation 108 may be about 0.1 seconds to about 100 seconds, or about 1 second to about 100 seconds, or about 40 seconds to about 60 seconds.

In an operation 110, the process chamber may be purged. Purging the chamber may involve flowing a purge gas or a sweep gas, which may be a carrier gas used in other operations or may be a different gas. In some embodiments, purging may involve evacuating the chamber. Example purge gases include argon, hydrogen, nitrogen, and helium. In various embodiments, the purge gas is an inert gas. The purge gas may include one or more gases. In some embodiments, operation 110 may include one or more evacuation subphases for evacuating the process chamber. Alternatively, it will be appreciated that operation 110 may be omitted in some embodiments. Operation 110 may have any suitable duration, such as about 0 seconds to about 60 seconds, for example about 0.01 seconds. In some embodiments, increasing a flow rate of one or more purge gases may decrease the duration of operation 110. For example, a purge gas flow rate may be adjusted according to various reactant thermodynamic characteristics and/or geometric characteristics of the process chamber and/or process chamber plumbing for modifying the duration of operation 110. In one non-limiting example, the duration of a purge phase may be adjusted by modulating purge gas flow rate. This may reduce deposition cycle time, which may improve substrate throughput. After a purge, the silicon-containing precursor molecules remain adsorbed onto the substrate surface. In some embodiments, the silicon-containing precursor is flowed to a chamber housing the substrate at a flow rate between about 1000 sccm and about 5000 sccm.

In an operation 112, a nitrogen-containing reactant is introduced to the process chamber which reacts with adsorbed silicon-containing precursor to form silicon nitride. In various embodiments, the nitrogen-containing reactant reacts with the silicon-containing precursor in a thermal reaction. In various embodiments, the nitrogen-containing reactant reacts with the silicon-containing precursor in a plasma-free reaction. In various embodiments, the nitrogen-containing reactant is introduced to the process chamber in a plasma-free environment. The nitrogen-containing reactant may be introduced in a plasma-free environment. The nitrogen-containing reactant may react thermally with the silicon nitride deposition precursor to form silicon nitride. In various embodiments, the nitrogen-containing reactant reacts with the silicon nitride deposition precursor to undergo a thermal ALD process.

In various embodiments, one or more process conditions used during operation 112 may be modulated to modify the silicon content of the deposited silicon nitride. For example, conversion time of operation 112 may be modulated to form a silicon-rich film. Other process conditions may also be modulated to form a silicon-rich silicon nitride. One method of forming a silicon-rich silicon nitride is by modulating the exposure time of operation 112. For example, the nitrogen-containing reactant may be introduced for a time of about 1 second to about 120 seconds. The ratio of dose time to conversion time may be about 1:1 to about 10:4.

Other process conditions that may be modulated include reactant flow rate, chamber pressure, temperature, and dilution. In some embodiments, the flow rate of the nitrogen-containing reactant may be about 2000 sccm to about 10000 sccm; for example, ammonia gas may be flowed using a flow rate of about 2000 sccm to about 10000 sccm, for a single-station chamber. In some embodiments, a hydrogen-containing gas is flowed with the nitrogen-containing reactant. For example, one hydrogen-containing gas that may be used includes hydrogen gas. The hydrogen gas can be flowed using a flow rate of about 0 sccm to about 5000 sccm for a single-station chamber. During operation 112, the chamber pressure may be about 5 Torr to about 25 Torr. In some embodiments, nitrogen gas is also co-flowed with ammonia and optionally hydrogen gas. For example, the nitrogen gas may be flowed at a flow rate of about 500 sccm to about 2000 sccm to dilute the nitrogen-containing gas. In some embodiments, nitrogen gas is used in lieu of ammonia.

In an operation 114, the chamber may be purged yet again. In some embodiments, this operation is performed before operation 112, or after operation 112, or both before and after operation 112. The process conditions and technique used for operation 114 may be the same as or similar to that of operation 110.

In various embodiments, operations 108-114 may be repeated multiple times. Each repetition of operations 108-114 may constitute a cycle. Cycles may be repeated until the desired silicon nitride film is deposited.

In some embodiments, forming a silicon-rich silicon nitride film may involve operations 102, 104, 108, 110, 112, and 114, and cycles of operations 108-114. In some embodiments, forming a silicon-rich silicon nitride film involves operations 108-114 without pre-treatment with heat or with plasma, and durations of operation 108 and 112 are modulated to allow a silicon-rich film to be formed. For example, the ratio of duration of operation 108 to operation 112 may be about 5:1 to about 5:4. In some embodiments, the ratio of duration of operation 108 to duration of operation 112 is about 1x: 3x to about 10x: 12x where x is about 0.2 second to about 10 seconds, or about 5 seconds to about 10 seconds. In various embodiments, the silicon nitride has an atomic ratio of silicon to nitrogen of at least about 0.69, or at least about 1.

In various embodiments, the step coverage of silicon nitride films using certain disclosed embodiments is at least about 80% or at least about 90% or about 100%. The silicon to nitrogen content of silicon nitride films deposited using certain disclosed embodiments is tunable from about 0.69 to about 1.10. Hydrogen content of the deposited silicon nitride can also be controlled by modulating process conditions of operations 108 and 112 such as the exposure times, dose times, or conversion times.

FIG. 1B shows another process flow diagram depicting operations that may be performed in accordance with certain disclosed embodiments. In an operation 142, a substrate having silicon oxide is provided to a process chamber. The substrate may be a silicon wafer, e.g., a 200-mm wafer, or a 300-mm wafer, including wafers having one or more layers of material, such as dielectric, conducting, or semi-conducting material deposited thereon. Non-limiting examples of under-layers include dielectric layers and conducting layers, e.g., silicon oxides, silicon nitrides, silicon carbides, metal oxides, metal nitrides, metal carbides, and metal layers.

In some embodiments, the process chamber is a single-wafer chamber. In some embodiments, the process chamber is a single-wafer station in a multi-station chamber, such as a 4-station chamber. In some embodiments, the process chamber is a furnace chamber. An example of a process chamber is further described below with respect to FIG. 3.

In some embodiments, operations in FIG. 1B are performed at the same chamber pressure, such as between about 0.5 Torr and about 50 Torr. In some embodiments, operations in FIG. 1B are performed in different chambers or at different pressures. In some embodiments, a multi-station chamber is used such that each station is set at a different pressure, and a substrate may be shuttled between stations during processing such that one or more operations are performed in different stations.

In some embodiments, operations in FIG. 1B are performed at the same temperature, such as about 500° C. to about 650° C., or less than about 850° C., or less than about 700° C., or less than about 650° C., or about 650° C. Temperature may refer to pedestal temperature or substrate temperature which is understood to be the temperature that the pedestal is set at to heat or cool the substrate to the set temperature. In some embodiments, operations in FIG. 1B are performed in different chambers having different pedestal temperatures or at different temperatures. In some embodiments, a multi-station chamber is used such that each station is set at a different temperature, and a substrate may be shuttled between stations during processing such that one or more operations are performed in different stations.

In operation 146, the silicon oxide surface is treated with a nitrogen-containing plasma. Use of a nitrogen-containing plasma may be performed to reduce nucleation delay of silicon nitride deposition on the silicon oxide surface.

The treatment may be any of the treatment described above with respect to operation 106 of FIG. 1A. In some embodiments, the treatment is a nitrogen-containing plasma treatment. The plasma may be generated using a plasma power of about 500 W to about 10000 W, or about 500 W to about 4000 W, or about 1000 W to about 4000 W, or about 2000 W to about 4000 W for a single-station chamber. Plasma may be generated by any suitable technique.

The flow rate of the nitrogen-containing gas depends on the nitrogen-containing gas selected and the mixture of gases used. For example, in a mixture of nitrogen gas and ammonia, the percentage of nitrogen gas may be about 0% to about 100% and the percentage of ammonia gas may be about 0% to about 100%, where the sum total of the percentage of nitrogen gas and ammonia gas for the total flow of nitrogen-containing gas is 100%. For example, in one non-limiting example, a 40% nitrogen gas and 60% ammonia gas mixture is used. The relative flow rates of nitrogen gas and ammonia gas may be about 1:10 to about 200:1.

In some embodiments, nitrogen gas may be flowed to a single-station chamber, in a mixture or alone, at a flow rate of about 1 slm to about 50 slm, or about 10 slm to about 30 slm. In some embodiments, ammonia gas may be flowed to a single-station chamber, in a mixture or alone, at a flow rate of about 100 sccm to about 10000 sccm or between about 4000 sccm and about 5000 sccm.

The duration of plasma treatment depends on a variety of factors, including the material to be deposited, the surface to be deposited on, the precursors used for material deposition, and other process conditions. In various embodiments, plasma treatment may be performed for a duration about 30 seconds to about 30 minutes or about 1 minute to about 30 minutes or about 10 minutes to about 30 minutes. In various embodiments, operation 106 is performed only once before any silicon nitride is deposited. In some embodiments, operation 106 is performed on an exposed silicon oxide surface one before any silicon nitride is deposited.

Treatment with a nitrogen-containing plasma in operation 106 may be performed by flowing or introducing a nitrogen-containing plasma species generated or ignited using a nitrogen-containing gas in an upstream location or remote chamber, or by flowing or introducing a nitrogen-containing gas to the chamber and igniting the gas in situ. The nitrogen-containing gas may be any suitable nitrogen-containing gas, such as but not limited to nitrogen, ammonia, nitrous oxide, and combinations thereof. In various embodiments, a gas containing both nitrogen and hydrogen may be used. In various embodiments, a mixture of nitrogen-containing gases may be used, such as but not limited to a mixture of nitrogen and ammonia. The plasma species used to perform treatment may be ion-free. The plasma species used to perform treatment may be radical-based. In various embodiments, the plasma species is passed through a showerhead such that the substrate surface is exposed primarily to radicals. Radicals that may be used for plasma treatment include but are not limited to nitrogen radicals and hydrogen radicals. In some embodiments, the plasma is an inductively coupled plasma. In some embodiments, the plasma is a capacitively coupled plasma. In some embodiments, the plasma is a radical assisted plasma. In some embodiments, the plasma is an ion-free plasma. The more the substrate is exposed to more radicals, the more nucleation delay is reduced for subsequent silicon nitride deposition.

In an operation 148, a silicon nitride deposition precursor is introduced to the process chamber. This operation may use any of the precursors and process conditions described above with respect to operation 108 of FIG. 1A. In various embodiments, a silicon-and-chlorine-containing precursor is used. In some embodiments, dichlorosilane is introduced to the process chamber. In some embodiments, the silicon nitride precursor is trichlorosilane (SiHCl₃). In some embodiments, the silicon nitride precursor is hexachlorodisilane (HCDS). In some embodiments, the silicon nitride precursor is tetrachlorosilane (SiCl₄).

The deposition precursor may be any Group IV-containing precursor, such as a silicon-containing precursor. In some embodiments, the deposition precursor may be a germanium-containing precursor. In some embodiments, hydrogen gas is co-flowed to the chamber in addition to the deposition precursor and reactant. In various embodiments, the deposition precursor is an aminosilane.

The deposition precursor is selected based on the material to be deposited. For example, for deposition of silicon oxide, a silicon-containing precursor may be selected. Example silicon-containing precursors include silicon-containing precursors having the structure:

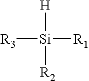

where R₁, R₂, and R₃ may be the same or different substituents, and may include silanes, amines, halides, hydrogen, or organic groups, such as alkylamines, alkoxy, alkyl, alkenyl, alkynyl, and aromatic groups.

Example silicon-containing precursors include polysilanes (H₃Si—(SiH₂)ₙ—SiH₃), where n≥1, such as silane, disilane, trisilane, tetrasilane; and trisilylamine:

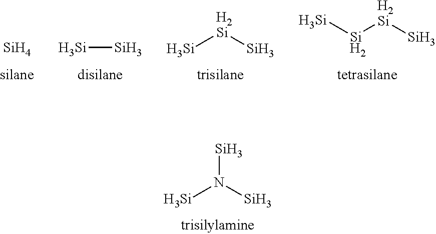

In some embodiments, the silicon-containing precursor is an alkoxysilane. Alkoxysilanes that may be used include, but are not limited to, the following:
Hₓ—Si—(OR)_{y} where x=1-3, x+y=4 and R is a substituted or unsubstituted alkyl group; and
Hₓ(RO)_{y}—Si—Si—(OR)_{y}Hₓ where x=1-2, x+y=3 and R is a substituted or unsubstituted alkyl group.

Examples of silicon-containing precursors include: tetraethyl orthosilicate (TEOS), TMOS (tetramethoxysilane), octamethylcyclotetrasiloxane (OMCTS); methylsilane; trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

As noted above, in some embodiments, the silicon-containing precursor may be an aminosilane, with hydrogen atoms, such as bisdiethylaminosilane, diisopropylaminosilane (DIPAS), tert-butylamino silane (BTBAS), tris(dimethylamino)silane (3DMAS), or 1-dimethylamino-1,1,5,5,5,-pentamethyl disiloxane, or di-sec-butylaminosilane (DSBAS). Aminosilane precursors include, but are not limited to, the following: Hₓ—Si—(NR)_{y} where x=1-3, x+y=4 and R is an organic or hydride group.

In some embodiments, the silicon nitride deposition precursor is a halosilane such as any of those described above with respect to operation 108 of FIG. 1.

In one example, the silicon nitride deposition precursor is flowed at a flow rate of about 100 sccm to about 2000 sccm for a single-station chamber. Duration of operation 148 in a single dose or in a single exposure may be about 0.1 second to about 10 seconds. The chamber pressure is about 5 Torr to about 25 Torr. In some embodiments, nitrogen gas is introduced with or co-flowed with the silicon nitride deposition precursor for dilution. In some embodiments, nitrogen gas is flowed for a duration of about 500 sccm to about 2000 sccm. In some embodiments, operation 148 is performed in a plasma-free environment.

In an operation 150, the process chamber is optionally purged. Purging may be performed using any of the process conditions or techniques described above with respect to operation 110 in FIG. 1A. In some embodiments, purging is performed by flowing a purge gas, such as nitrogen gas. The purge gas may be flowed at a flow rate of about 1000 sccm to about 40000 sccm for a single-station chamber. The purging operation may be performed for a duration of about 0.1 second to about 10 seconds. The chamber pressure may be about 0.5 Torr to about 25 Torr. In some embodiments, a low pressure, such as less than about 0.1 Torr, may be used to purge more effectively.

In an operation 152, a nitrogen-containing reactant is introduced to the process chamber to form silicon nitride on the substrate surface. The nitrogen-containing reactant may be introduced in a plasma-free environment. The nitrogen-containing reactant may react thermally with the silicon nitride deposition precursor to form silicon nitride. In various embodiments, the nitrogen-containing reactant reacts with the silicon nitride deposition precursor to undergo a thermal ALD process.

The nitrogen-containing reactant may be any nitrogen-containing reactant such as nitrogen gas, ammonia gas, or combinations thereof. In some embodiments, the nitrogen-containing gas contains hydrogen. In some embodiments, the nitrogen-containing gas is introduced with hydrogen gas. The process chemistry and process conditions for operation 152 may be any of those described above with respect to operation 112 in FIG. 1A.

In one example, operation 152 involves flowing ammonia gas using a flow rate of about 2000 sccm to about 10000 sccm with hydrogen gas using a flow rate of about 0 sccm to about 5000 sccm, where flow rates are for a single-station chamber, for a duration of about 1 second to about 30 seconds, using a chamber pressure of about 5 Torr to about 25 Torr. In some embodiments, nitrogen gas is also flowed for dilution using a flow rate of about 500 sccm to about 2000 sccm.

In operation 154, the process chamber may again be optionally purged. Purging may be performed using any of the process conditions or techniques described above with respect to operation 110 in FIG. 1A. In some embodiments, purging is performed by flowing a purge gas, such as nitrogen gas. The purge gas may be flowed at a flow rate of about 1000 sccm to about 40000 sccm for a single-station chamber. The purging operation may be performed for a duration of about 0.1 second to about 10 seconds. The chamber pressure may be about 0.5 Torr to about 25 Torr. In some embodiments, a low pressure, such as less than about 0.1 Torr, may be used to purge more effectively.

Operation 148-154 may be repeated in one or more cycles. Each repetition of operations 148-154 may constitute a cycle. Cycles may be repeated until the desired silicon nitride film is deposited. In some embodiments, a cycle includes only operations 148 and 152. In some embodiments, a cycle includes operations 148, 150, and 152. In some embodiments, a cycle includes operations 150, 152, and 154. In some embodiments, a cycle includes operations 148, 150, 152, and 154.

FIG. 2 shows an example timing schematic for phases overtime that may be performed in one embodiment of certain disclosed embodiments. FIG. 2 shows a process 200 having a pre-treatment phase 206A prior to two deposition cycles 200A and 200B. For each phase, whether inert gas, treatment gas, silicon precursor gas, and second reactant gas are flowed are depicted, as well as whether the plasma is turned on or turned off. During the pre-treatment phase 206A, an inert gas may be flowed along with a treatment gas while silicon precursor gas and second reactant gas flows are off, with the plasma turned on. Pre-treatment phase 206A may correspond to operation 106 of FIG. 1A or operation 146 of FIG. 1B. Pre-treatment may be performed before any silicon nitride is deposited on the substrate. In some embodiments, pre-treatment is performed on an exposed silicon oxide surface on the substrate.

Deposition cycle 200A includes precursor phase 208A, purge phase 210A, conversion phase 212A, and purge phase 214A. While deposition cycle 200A includes purge phases, it will be understood that in certain embodiments, one or more purge phases may not be performed. During precursor phase 208A, the silicon precursor flow is turned on while the treatment gas flow is turned off, and the inert gas may continue to flow (as a carrier gas, dilution gas, delivery gas, or any of the above), while second reactant flow remains off and plasma is turned off. Precursor phase 208A may correspond to operation 108 of FIG. 1A or operation 148 of FIG. 1B. Returning to FIG. 2, following precursor phase 208A, a purge phase 210A is performed. During purge phase 210A, the inert gas, such as a purge gas, may continue to flow while the treatment gas and second reactant gases remain off. During purge phase 210A, the silicon precursor gas is turned off and the plasma remains off. Purge phase 210A may correspond to operation 110 of FIG. 1A or operation 150 of FIG. 1B. Returning to FIG. 2, following purge phase 210A, a conversion phase 212A may be performed. During conversion phase 212A, inert gas may continue to flow, and second reactant gas is turned on. An example second reactant gas may be ammonia. The second reactant gas may include one or more gases. During conversion phase 212A, treatment gas flow remains off, silicon precursor gas flow remains off, and plasma remains off. Conversion phase 212A may correspond to operation 112 of FIG. 1A, or operation 152 of FIG. 1B. Returning to FIG. 2, following conversion phase 212A, a purge phase 214A may be performed. During purge phase 214A, an inert gas, such as a purge gas, may continue to flow while treatment gas flow remains off and silicon precursor gas flow also remains off. Second reactant flow is turned off and plasma remains off. Purge phase 214A may correspond to operation 114 of FIG. 1A or operation 154 of FIG. 1B. Returning to FIG. 2, following deposition cycle 200A, a second deposition cycle 200B may be performed that repeats certain operations. Deposition cycle 200B includes precursor phase 206B, purge phase 210B, conversion phase 212B, and purge phase 214B. Although only two deposition cycles are depicted in FIG. 2, it will be understood that in some embodiments, fewer or more cycles may be performed to deposit a desired thickness of silicon nitride. During precursor phase 208B, the silicon precursor flow is turned on while the treatment gas flow remains turned off, and the inert gas may continue to flow (as a carrier gas, dilution gas, delivery gas, or any of the above), while second reactant flow remains off and plasma remains off. Precursor phase 208B may correspond to a repeated operation 108 of FIG. 1A or a repeated operation 148 of FIG. 1B. Returning to FIG. 2, following precursor phase 208B, a purge phase 210B is performed. During purge phase 210B, the inert gas, such as a purge gas, may continue to flow while the treatment gas and second reactant gases remain off. During purge phase 210B, the silicon precursor gas is turned off and the plasma remains off. Purge phase 210B may correspond to a repeated operation 110 of FIG. 1A or a repeated operation 150 of FIG. 1B. Returning to FIG. 2, following purge phase 210B, a conversion phase 212B may be performed. During conversion phase 212B, inert gas may continue to flow, and second reactant gas is turned on. An example second reactant gas may be ammonia. The second reactant gas may include one or more gases. During conversion phase 212B, treatment gas flow remains off, silicon precursor gas flow remains off, and plasma remains off. Conversion phase 212B may correspond to a repeated operation 112 of FIG. 1A, or a repeated operation 152 of FIG. 1B.

Certain disclosed embodiments may be used for forming silicon-rich silicon nitride films. Silicon-rich silicon nitride films may have more silicon dangling bonds which allows greater density control for forming high energy traps used in a silicon nitride charge trap layer. Silicon-rich silicon nitride films decrease the hydrogen content as compared to a stoichiometric silicon nitride film by about 50% to about 90%. In various embodiments, silicon-rich silicon nitride films deposited using certain disclosed embodiments can achieve at least about 80% or at least about 90% or about 100% or 100% conformality. For example, silicon-rich silicon nitride films may be formed by modulating the dose time and/or conversion time. In various embodiments, the density of the silicon nitride film may be about 2.5 g/cc to about 3.0 g/cc. In various embodiments, the wet etch rate of a silicon nitride in 100:1 diluted hydrofluoric acid is about 2 Å/min to about 3 Å/min. In various embodiments, the refractive index of silicon nitride is about 2 Å/min to about 3 Å/min. The deposition rate may be about 0.4 Å/cycle to about 6 Å/cycle.

Certain disclosed embodiments may be used for forming silicon nitride on silicon oxide surfaces with reduced nucleation delay. For example, plasma treatment may be used to reduce nucleation delay prior to depositing any silicon nitride. Plasma treatment may involve flowing ammonia gas, nitrogen gas, or both and igniting a plasma. Under the same process conditions, the thickness of silicon nitride deposited increases with plasma treatment, with silicon nitride deposited after ammonia treatment having greater thickness than silicon nitride deposited after nitrogen plasma treatment, and silicon nitride deposited after nitrogen plasma treatment having a greater thickness than silicon nitride deposited without any plasma treatment. Silicon nitride deposition using plasma treatment remains more selective on silicon surfaces than on silicon oxide surfaces. Pattern loading effects are reduced when plasma treatment is performed prior to silicon nitride deposition.

### Apparatus

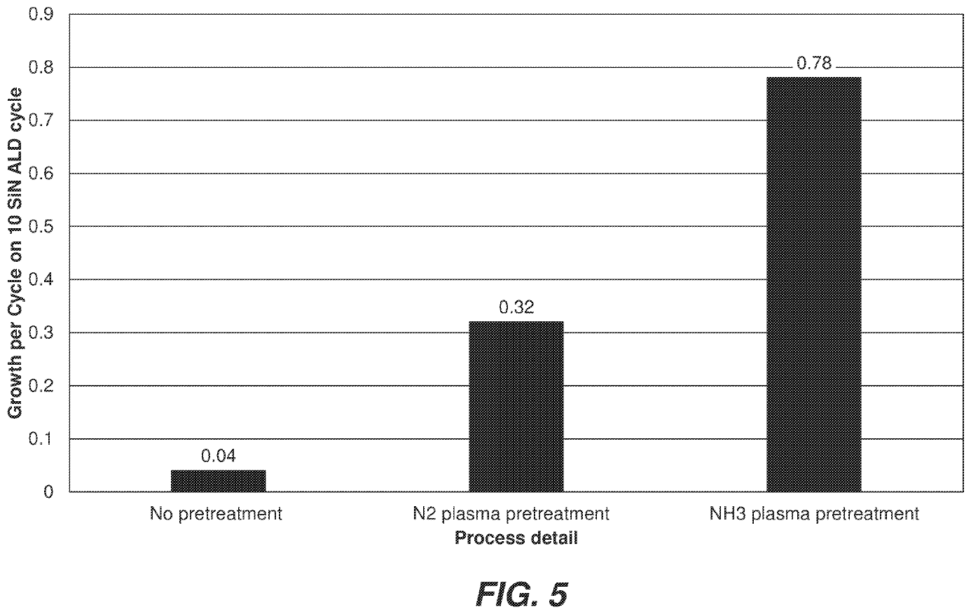

FIG. 3 depicts a schematic illustration of an embodiment of an atomic layer deposition (ALD) process station 300 having a process chamber body 302 for maintaining a low-pressure environment. A plurality of ALD process stations 300 may be included in a common low pressure process tool environment. For example, FIG. 5 depicts an embodiment of a multi-station processing tool 300. In some embodiments, one or more hardware parameters of ALD process station 300 including those discussed in detail below may be adjusted programmatically by one or more computer controllers 350.

ALD process station 300 fluidly communicates with reactant delivery system 301 for delivering process gases to a showerhead 306. Reactant delivery system 301 includes a mixing vessel 304 for blending and/or conditioning process gases, such as a silicon-containing precursor gas, or nitrogen-containing gas, for delivery to showerhead 306. One or more mixing vessel inlet valves 320 may control introduction of process gases to mixing vessel 304. One or more valves 305 may control introduction of gases to the showerhead 306.

As an example, the embodiment of FIG. 3 includes a vaporization point 303 for vaporizing liquid reactant to be supplied to the mixing vessel 304. In some embodiments, vaporization point 303 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput.

Thus, in some embodiments, delivery piping downstream of vaporization point 303 may be heat traced. In some examples, mixing vessel 304 may also be heat traced. In one non-limiting example, piping downstream of vaporization point 303 has an increasing temperature profile extending from approximately 40° C. to approximately −55° C. or from about 60° C. to about 65° C. at mixing vessel 304.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 303. In one scenario, a liquid injector may be mounted directly to mixing vessel 304. In another scenario, a liquid injector may be mounted directly to showerhead 306.

In some embodiments, a liquid flow controller (LFC) upstream of vaporization point 303 may be provided for controlling a mass flow of liquid for vaporization and delivery to ALD process station 300. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 306 distributes process gases toward substrate 312. In the embodiment shown in FIG. 3, the substrate 312 is located beneath showerhead 306 and is shown resting on a pedestal 308. Showerhead 306 may have any suitable shape, and may have any suitable number and arrangement of ports for distributing process gases to substrate 312.

In some embodiments, pedestal 308 may be raised or lowered to expose substrate 312 to a volume 307 between the substrate 312 and the showerhead 306. It will be appreciated that, in some embodiments, pedestal height may be adjusted programmatically by a suitable computer controller 350.

In another scenario, adjusting a height of pedestal 308 may allow a plasma density to be varied during plasma activation in the process in embodiments where a plasma is ignited. At the conclusion of the process phase, pedestal 308 may be lowered during another substrate transfer phase to allow removal of substrate 312 from pedestal 308.

In some embodiments, pedestal 308 may be temperature controlled via heater 310. In some embodiments, the pedestal 308 may be heated to a temperature of about 25° C. to about 800° C., or about 200° C. to about 700° C., during deposition of silicon nitride films as described in disclosed embodiments. In some embodiments, the pedestal is set at a temperature of about 25° C. to about 800° C., or about 200° C. to about 300° C.

Further, in some embodiments, pressure control for ALD process station 300 may be provided by butterfly valve 318. As shown in the embodiment of FIG. 3, butterfly valve 318 throttles a vacuum provided by a downstream vacuum pump (not shown). However, in some embodiments, pressure control of ALD process station 300 may also be adjusted by varying a flow rate of one or more gases introduced to the ALD process station 300.

In some embodiments, a position of showerhead 306 may be adjusted relative to pedestal 308 to vary a volume between the substrate 312 and the showerhead 306. Further, it will be appreciated that a vertical position of pedestal 308 and/or showerhead 306 may be varied by any suitable mechanism within the scope of the present disclosure. In some embodiments, pedestal 308 may include a rotational axis for rotating an orientation of substrate 312. It will be appreciated that, in some embodiments, one or more of these example adjustments may be performed programmatically by one or more suitable computer controllers 350.

In some embodiments where plasma may be used as discussed above, showerhead 306 and pedestal 308 electrically communicate with a radio frequency (RF) power supply 314 and matching network 316 for powering a plasma. For example, plasma may be used for treating a silicon oxide surface prior to depositing silicon nitride. In some embodiments, the plasma energy may be controlled by controlling one or more of a process station pressure, a gas concentration, an RF source power, an RF source frequency, and a plasma power pulse timing. For example, RF power supply 314 and matching network 316 may be operated at any suitable power to form a plasma having a desired composition of radical species. Examples of suitable powers are about 150 W to about 6000 W for a single-station chamber. For a 4-station chamber, the plasma power may include four generator each powered up to about 6000 W, for a total of about 24000 W. For treating a silicon oxide surface, the substrate may be exposed to a nitrogen-containing gas, or a mixture of nitrogen-containing gases and optional inert gases while igniting a plasma using the RF power supply 314 and matching network 316.

In some embodiments, the substrate may be exposed to nitrogen-containing gas while igniting a plasma to treat a silicon oxide surface using plasma powers such as between about 500 W and about 6000 W per surface area of a 300 mm wafer. The plasma may be generated remotely (such as in a remote plasma generator) or directly in a chamber housing the substrate (i.e. in situ).

RF power supply 314 may provide RF power of any suitable frequency. In some embodiments, RF power supply 314 may be configured to control high- and low-frequency RF power sources independently of one another. Example low-frequency RF frequencies may include, but are not limited to, frequencies between 0 kHz and 500 kHz or up to about 2 MHz. Example high-frequency RF frequencies may include, but are not limited to, frequencies between 1.8 MHz and 2.45 GHz, or greater than about 13.56 MHz, or greater than 27 MHz, or greater than 30 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

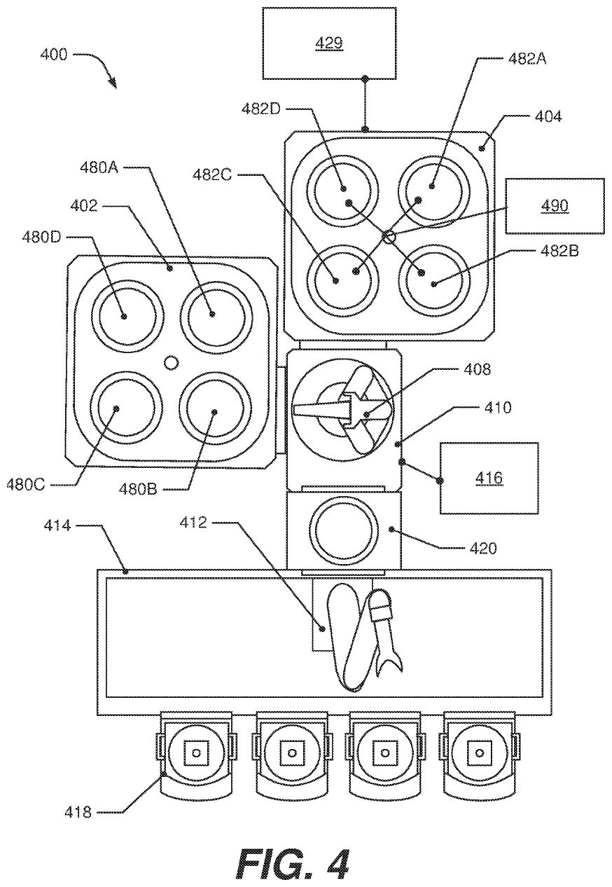

In some embodiments, instructions for a controller 350 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of a treatment gas such as a nitrogen-containing gas, instructions for setting a flow rate of a carrier gas (such as argon), and time delay instructions for the first recipe phase. A second recipe phase may include instructions for setting a flow rate of an inert and/or silicon-containing precursor gas, instructions for setting a flow rate of a carrier gas (such as argon), and time delay instructions for a second recipe phase. A third, subsequent recipe phase may include instructions for modulating or stopping a flow rate of an inert and/or a reactant gas, and instructions for modulating a flow rate of a carrier or purge gas and time delay instructions for the third recipe phase. A fourth recipe phase may include instructions for modulating a flow rate of a nitrogen-containing gas, instructions for modulating the flow rate of a carrier or purge gas, and time delay instructions for the fourth recipe phase. A fifth, subsequent recipe phase may include instructions for modulating or stopping a flow rate of an inert and/or a reactant gas, and instructions for modulating a flow rate of a carrier or purge gas and time delay instructions for the fifth recipe phase. It will be appreciated that these recipe phases may be further subdivided and/or iterated in any suitable way within the scope of the disclosed embodiments. In some embodiments, the controller 350 may include any of the features described below with respect to system controller 450 of FIG. 4.

As described above, one or more process stations may be included in a multi-station processing tool. FIG. 4 depicts an example processing apparatus according to disclosed embodiments. Tool 400 includes a first processing chamber 402 and a second processing chamber 404. The first processing chamber 402 includes a plurality of processing stations, four stations 480A-D, that each may process a wafer. The first processing chamber 402 is configured to perform plasma treatment operations on the wafers. The second processing chamber 404 is configured to perform deposition on the wafer and may be considered a deposition chamber. The second processing chamber 404 also includes a plurality of processing stations, four stations 482A-D, that each may process a wafer and may be controlled by a controller 490 which may be integrated with system controller 429. The first and second processing chambers 402 and 404 may be considered multi-station processing chambers.

Tool 400 also includes a wafer transfer unit configured to transport one or more wafers within the tool 400. Additional features of tool 400 will be discussed in greater detail below, and various features are discussed here with respect to some of the described techniques. In the depicted illustration, the wafer transfer unit includes a first robotic arm unit 408 in a first wafer transfer module 410 and a second robotic arm unit 412 in a second wafer transfer module 414 that may be considered an equipment front end module (EFEM) configured to received containers for wafers, such as a front opening unified pod (FOUP) 418. The first robotic arm unit 408 is configured to transport a wafer between the first processing chamber 402 and the second processing chamber 404, and between the second the second robotic arm unit 412. The second robotic arm unit 412 is configured to transport the wafer between a FOUP and the first robotic arm unit 408. After a wafer has been treated in the first processing chamber 402, the wafer transfer unit is able to transfer the wafer from the first processing chamber 402, to the second processing chamber 404 where one or more layers of encapsulation material may be deposited on one or more wafers.

Similar to above, the first wafer transfer module 410 may a vacuum transfer module (VTM). Airlock 420, also known as a loadlock, is shown and may be individually optimized to perform various fabrication processes. The tool 400 also includes a FOUP 418 that is configured to lower the pressure of the tool 400 to a vacuum or low pressure, e.g., between about 1 mTorr and about 10 Torr, and maintain the tool 400 at this pressure. This includes maintaining the first and second processing chambers 402 and 404, and the first wafer transfer module 410 at the vacuum or low pressure. The second wafer transfer module 414 may be at a different pressure, such as atmospheric. As the wafer is transferred throughout the tool 400, it is therefore maintained at the vacuum or low pressure. For example, as the wafer is transferred from the first processing chamber 402, into the first wafer transfer module 410, and to the second processing chamber 404, the wafer is maintained at the vacuum or low pressure and not exposed to atmospheric pressure.

In a further example, a substrate is placed in one of the FOUPs 418 and the second robot arm unit 412, or front-end robot, transfers the substrate from the FOUP 418 to an aligner, which allows the substrate to be properly centered before it is etched, or deposited upon, or otherwise processed. After being aligned, the substrate is moved by the second robot arm unit 412 into the airlock 420. Because airlock modules have the ability to match the environment between an ATM and a VTM, the substrate is able to move between the two pressure environments without being damaged. From the airlock 420, the substrate is moved by the first robot arm unit 408 through the first wafer transfer module 410, or VTM 410, and into the first processing chamber 402. In order to achieve this substrate movement, the first robot arm unit 408 uses end effectors on each of its arms.

FIG. 4 also depicts an embodiment of a system controller 429 employed to control process conditions and hardware states of tool 400. System controller 429 may include one or more memory devices (not shown), one or more mass storage devices (not shown), and one or more processors (not shown). Processors may include a CPU or computer, analog, and/or digital input/output connections, stepper motor controller boards, etc.

In some embodiments, system controller 429 controls all of the activities of tool 400. System controller 429 executes system control software stored in mass storage device, loaded into memory device, and executed on processor. Alternatively, the control logic may be hard coded in the system controller 429. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software may include instructions for controlling the timing, mixture of gases, gas flow rates, chamber and/or station pressure, chamber and/or station temperature, wafer temperature, target power levels, RF power levels, substrate pedestal, chuck and/or susceptor position, and parameters of a particular process performed by tool 400. System control software may be configured in any suitable way. For example, various process tool component subroutines or control objects may be written to control operation of the process tool components used to carry out various process tool processes. System control software may be coded in any suitable computer readable programming language.

In some embodiments, system control software may include input/output control (IOC) sequencing instructions for controlling the various parameters described above. Other computer software and/or programs stored on mass storage device and/or memory device associated with system controller 429 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal and to control the spacing between the substrate and other parts of tool 400.

A process gas control program may include code for controlling gas composition (e.g., silicon-containing precursor gases, nitrogen-containing gases, carrier gases, inert gases, and/or purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium or nitrogen) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 429. The user interface may include a display screen, graphical software displays of the apparatus and/or process conditions, and user input devices such as pointing devices, keyboards, touch screens, microphones, etc.

In some embodiments, parameters adjusted by system controller 429 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 429 from various process tool sensors. The signals for controlling the process may be output on the analog and digital output connections of tool 400. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 429 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 429 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 429.

In some implementations, the system controller 429 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 429, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 429 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 429 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 429, in some implementations, may be a part of or coupled to a computer that is integrated with, coupled to the system, otherwise networked to the system, or a combination thereof. For example, the system controller 429 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 429 receives instructions in the form of data, which specify parameters for each of the processing steps to be performed during one or more operations. It should be understood that the parameters may be specific to the type of process to be performed and the type of tool that the system controller 429 is configured to interface with or control. Thus as described above, the system controller 429 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 429 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

An appropriate apparatus for performing the methods disclosed herein is further discussed and described in U.S. patent application Ser. No. 13/084,399 (now U.S. Pat. No. 8,728,956), filed Apr. 11, 2011, and titled “PLASMA ACTIVATED CONFORMAL FILM DEPOSITION”; and Ser. No. 13/084,305, filed Apr. 11, 2011, and titled “SILICON NITRIDE FILMS AND METHODS,” each of which is incorporated herein in its entireties.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### EXPERIMENTAL

### Experiment 1

An experiment was conducted on multiple substrates. On a first substrate, silicon nitride was deposited on a non-treated silicon oxide surface using 10 cycles of atomic layer deposition (ALD). On a second substrate, silicon nitride was deposited on a non-treated bare silicon surface using 10 cycles of ALD. On a third substrate, a non-treated silicon oxide surface was exposed to nitrogen plasma treatment and then silicon nitride was deposited on the treated silicon oxide surface using 10 cycles of ALD. On a fourth substrate, a non-treated silicon surface was exposed to nitrogen plasma treatment and then silicon nitride was deposited on the treated silicon surface using 10 cycles of ALD. On a fifth substrate, a non-treated silicon oxide surface was exposed to ammonia plasma treatment and then silicon nitride was deposited on the treated silicon oxide surface using 10 cycles of ALD. On a sixth substrate, a non-treated silicon surface was exposed to ammonia plasma treatment and then silicon nitride was deposited on the silicon surface using 10 cycles of ALD. In the above cycles of ALD, each cycle included a dose of a silicon-containing precursor for 5 seconds, a purge for 10 seconds, an ammonia exposure for 15 seconds, and a purge for 10 seconds.

The thickness and growth per cycle of the silicon nitride that was deposited on the second, fourth, and sixth substrates are provided in Table 1. Growth per cycle is depicted in FIG. 5.

TABLE 1
Thickness and Growth Per Cycle of SiN on Si

| | | SiN Thickness | Growth Per Cycle |
|---|---|---|---|
| Substrate | Treatment | (Å) | (Å/cyc) |
| Silicon | None | 0.4 | 0.04 |
| Silicon | N₂ plasma | 3.2 | 0.32 |
| Silicon | NH₃ plasma | 7.8 | 0.78 |

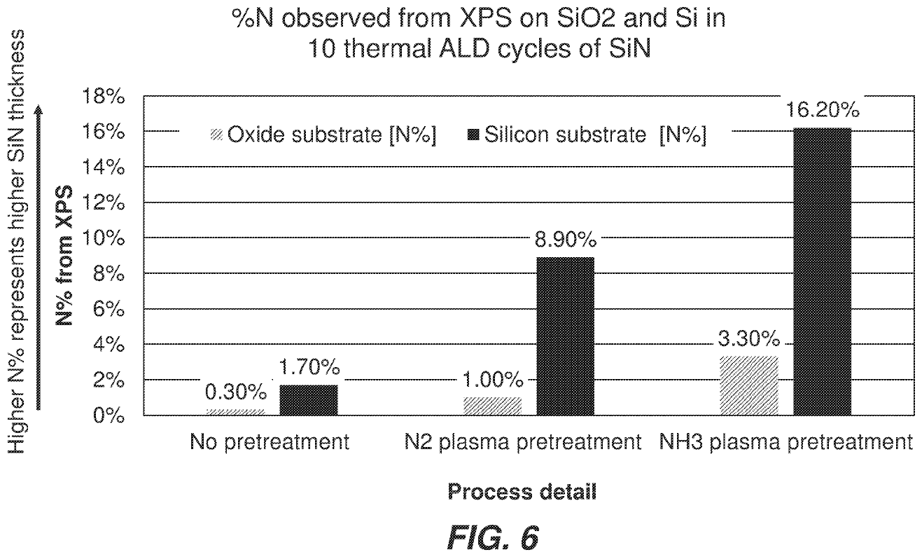

The resulting nitrogen content for each substrate is provided in Table 2. Changes in nitrogen content for each substrate and each plasma treatment and non-treatment type are depicted in FIG. 6.

TABLE 2
Nitrogen Content of SiN on Si and SiO₂

| Substrate | Treatment | Nitrogen Content via XPS |
|---|---|---|
| Silicon oxide | None | 0.3% |
| Silicon oxide | N₂ plasma | 1.0% |
| Silicon oxide | NH₃ plasma | 3.3% |
| Silicon | None | 1.7% |
| Silicon | N₂ plasma | 8.9% |
| Silicon | NH₃ plasma | 16.2% |

### Experiment 2

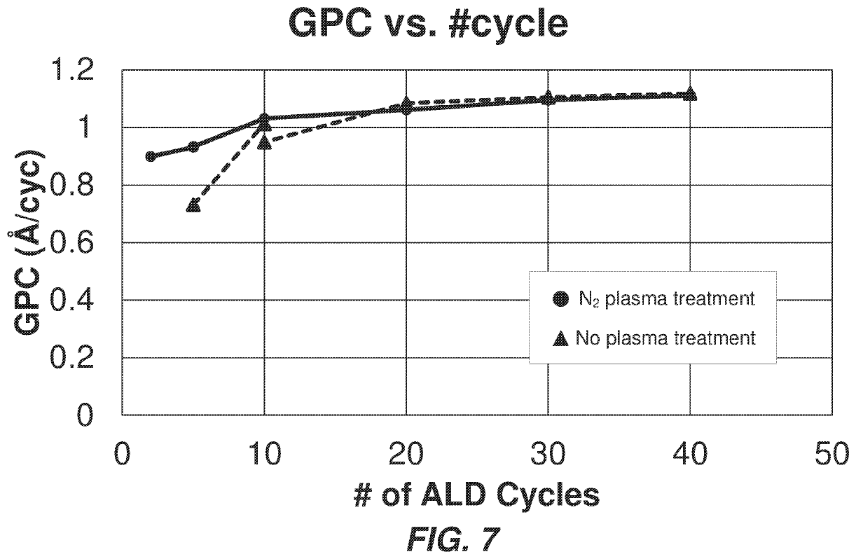

An experiment was conducted on substrates. On a first substrate, silicon nitride was deposited on a blanket non-treated silicon surface using ALD. On a second substrate, a blanket non-treated silicon surface was exposed to nitrogen plasma treatment and then silicon nitride was deposited on the treated silicon surface using ALD. The growth per cycle was measured and are graphed in FIG. 7. Silicon nitride deposited with a nitrogen plasma treatment performed prior to silicon nitride deposition exhibited greater growth per cycle, particularly in the early cycles of ALD.

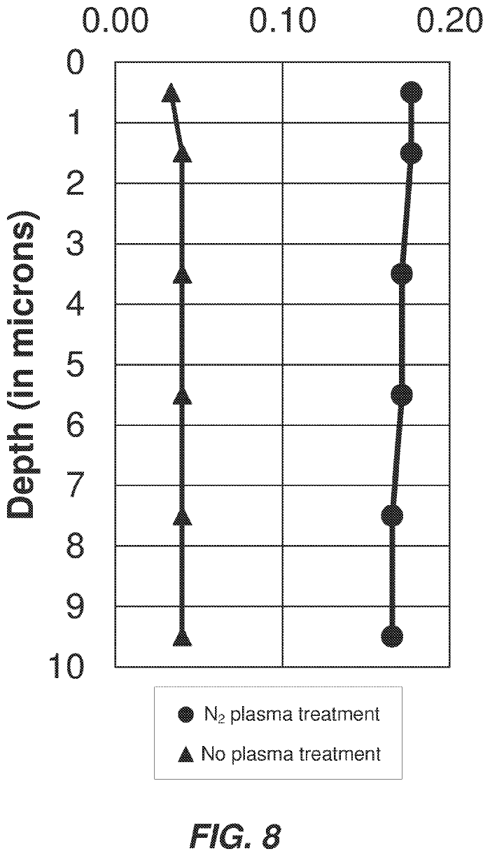

On a third substrate, silicon nitride was deposited in a feature having an aspect ratio of 30:1 and having a non-treated silicon surface using ALD. On a fourth substrate, a feature having an aspect ratio of 30:1 and having a non-treated silicon surface was exposed to nitrogen plasma treatment and then silicon nitride was deposited on the treated silicon surface using ALD. The growth of the silicon nitride on sidewalls of the two substrates was measured and are graphed in FIG. 8. The conformality of growth of silicon nitride deposited after nitrogen plasma was improved and nucleation delay was reduced as thicker growth per cycle was observed.

### Experiment 3

An experiment was conducted on patterned substrates having feature aspect ratios of about 180:1. Each substrate was patterned with features having an initial diameter D1. If the resulting diameter after deposition is D2, sidewall deposition can be determined by subtracting D2 from D1 and dividing by 2 per the below formula whereby X is the sidewall deposition amount:

$$X = \frac{D 1 - D 2}{2} \qquad Eqn . 1$$

Pattern loading is measured by dividing the deposition on the patterned wafer by the deposition on a non-patterned wafer. Silicon nitride was deposited on a first patterned substrate using ALD without plasma pretreatment. Silicon nitride was deposited on a second patterned substrate using nitrogen plasma pre-treatment at a chamber pressure of 3 Torr and 20 slm of nitrogen gas ignited using 3000 W of plasma power for a single wafer for 20 minutes followed by ALD. Silicon nitride was deposited on a third patterned substrate using ammonia plasma pre-treatment at a chamber pressure of 3 Torr and 4.5 slm of ammonia gas ignited using 3000 W of plasma power for a single wafer for 20 minutes followed by ALD. The amount of material deposited was measured by Critical Dimension Scanning Electron Microscope (CDSEM). Pattern loading was measured using Equation 2:

$$Eqn . 2$$

$$Pattern Loading = \frac{Deposition on patterned wafter ( A )}{Deposition on non - patterned / blanket wafer ( B )}$$

The resulting pattern loading exhibited in each of these substrates is shown in Table 3.

TABLE 3
Pattern Loading Effect

| | | Treatment | | Pattern |
|---|---|---|---|---|
| | | Plasma Power | | Loading |
| | Treatment | (Single- | Treatment | (CDSEM/ |
| Treatment | Gas Flow | station) | Duration | Blanket) |
| None | None | None | None | 8.0% |
| N₂ plasma | 20 slm N₂ | 3000 W | 20 min | 42.8% |
| NH₃ plasma | 4.5 slm NH₃ | 3000 W | 20 min | 62.1% |

### Experiment 4

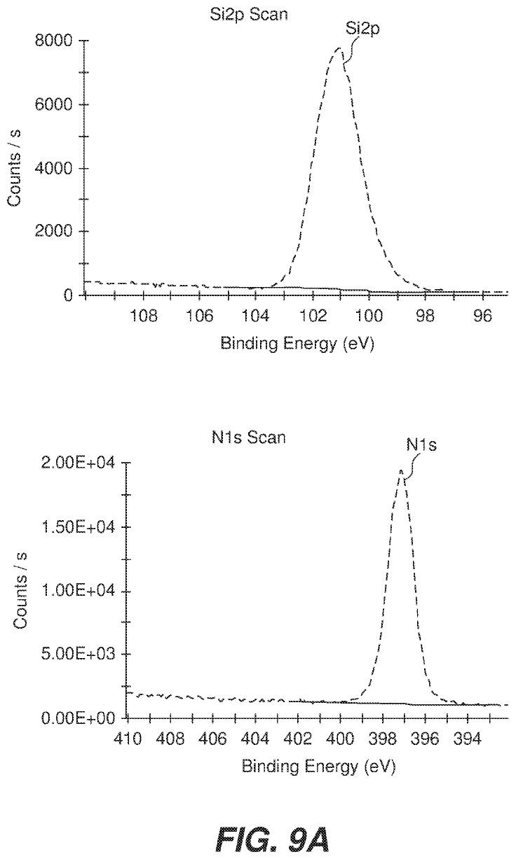

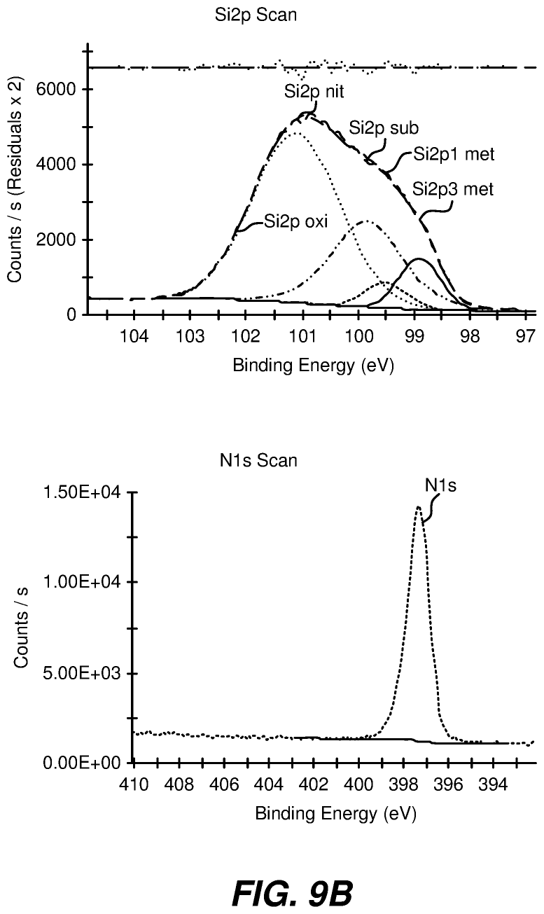

An experiment was conducted measuring the silicon content by XPS for silicon nitride deposited using a 1:1 dose to conversion time, and silicon nitride deposited dose time to conversion time ratio of about 10:4. The silicon (top) and nitrogen (bottom) XPS scan results for the 1:1 dose to conversion time ratio is shown in FIG. 9A. The silicon (top) to nitrogen (bottom) XPS scan results for the 10:4 dose to conversion time ratio is shown in FIG. 9B. The results are depicted in Table 4. The nitrogen to silicon atomic content ratio can be tuned from about 0.69 to about 1.10.

TABLE 4
Silicon and Nitrogen Content by XPS

| Dose Time to | | | |
|---|---|---|---|
| Conversion Time Ratio | Si Content | N Content | N/Si |
| 10:4 | 53.5 | 36.8 | 0.69 |
| 1:1 | 43.7 | 48.2 | 1.10 |

### Experiment 5

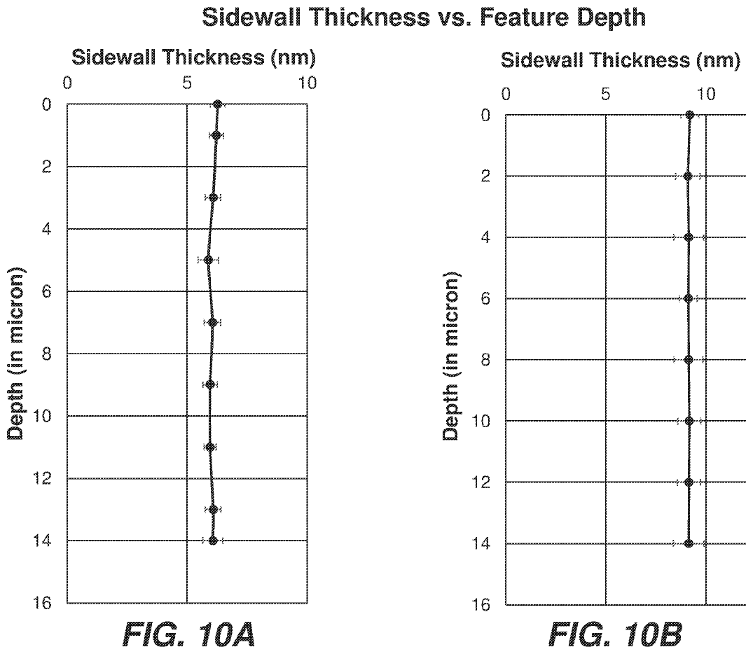

An experiment was conducted by depositing silicon nitride using modulated dose to conversion time ratios into features having an aspect ratio of 180:1. The sidewall thickness was measured at various depths into the feature. The sidewall thicknesses and depths of the silicon nitride deposited using a dose to conversion time ratio of about 1:1 is shown in FIG. 10A. The conformality of the silicon nitride film deposited using a dose to conversion time ratio of about 1:1 was about 90% to about 110%. The sidewall thicknesses and depths of the silicon nitride deposited using a dose to conversion time ratio of about 10:4 is shown in FIG. 10B. The conformality of the silicon nitride film deposited using a dose to conversion time ratio of about 10:4 was about 100%.

### Definitions

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl (—C(O)H), acetyl (Ac or —C(O)Me), propionyl, isobutyryl, butanoyl, and the like. In some embodiments, the acyl or alkanoyl group is —C(O)—R, in which R is hydrogen, an aliphatic group, or an aromatic group, as defined herein.

By “alkanoyloxy” is meant an alkanoyl group, as defined herein, attached to the parent molecular group through an oxy group, as defined herein. This group is exemplified by acetoxy (—OAc or —OC(O)Me). In some embodiments, the alkanoyloxy group is —OC(O)—R, in which R is hydrogen, an aliphatic group, or an aromatic group, as defined herein.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “aliphatic-carbonyl” is meant an aliphatic group that is or can be coupled to a compound disclosed herein, wherein the aliphatic group is or becomes coupled through a carbonyl group (—C(O)—). In some embodiments, the aliphatic-carbonyl group is —C(O)—R, in which R is an optionally substituted aliphatic group, as defined herein.

By “aliphatic-carbonyloxy” is meant an aliphatic group that is or can be coupled to a compound disclosed herein, wherein the aliphatic group is or becomes coupled through a carbonyloxy group (—OC(O)—). In some embodiments, the aliphatic-carbonyloxy group is —OC(O)—R, in which R is an optionally substituted aliphatic group, as defined herein.

By “aliphatic-oxy” is meant an aliphatic group that is or can be coupled to a compound disclosed herein, wherein the aliphatic group is or becomes coupled through an oxy group (—C(O)—). In some embodiments, the aliphatic-oxy group is —O—R, in which R is an optionally substituted aliphatic group, as defined herein.

By “aliphatic-oxycarbonyl” is meant an aliphatic group that is or can be coupled to a compound disclosed herein, wherein the aliphatic group is or becomes coupled through an oxycarbonyl group (—C(O)O—). In some embodiments, the aliphatic-oxycarbonyl group is —C(O)O—R, in which R is an optionally substituted aliphatic group, as defined herein.

By “alkyl-aryl,” “alkenyl-aryl,” and “alkynyl-aryl” is meant an alkyl, alkenyl, or alkynyl group, respectively and as defined herein, that is or can be coupled (or attached) to the parent molecular group through an aryl group, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl and/or aryl. Exemplary unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Exemplary unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₈ aryl). Exemplary unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₈ aryl). In some embodiments, the alkyl-aryl group is -L-R, in which L is an aryl group or an arylene group, as defined herein, and R is an alkyl group, as defined herein. In some embodiments, the alkenyl-aryl group is -L-R, in which L is an aryl group or an arylene group, as defined herein, and R is an alkenyl group, as defined herein. In some embodiments, the alkynyl-aryl group is -L-R, in which L is an aryl group or an arylene group, as defined herein, and R is an alkynyl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An exemplary alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl. Non-limiting alkenyl groups include allyl (All), vinyl (Vi), 1-butenyl, 2-butenyl, and the like.

By “alkoxy” is meant —OR, where R is an optionally substituted aliphatic group, as described herein. Exemplary alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkoxyalkyl” is meant an alkyl group, as defined herein, which is substituted with an alkoxy group, as defined herein. Exemplary unsubstituted alkoxyalkyl groups include between 2 to 12 carbons (C₂₋₁₂ alkoxyalkyl), as well as those having an alkyl group with 1 to 6 carbons and an alkoxy group with 1 to 6 carbons (i.e., C₁₋₆ alkoxy-C₁₋₆ alkyl). In some embodiments, the alkoxyalkyl group is -L-O—R, in which each of L and R is, independently, an alkyl group, as defined herein.

By “alkoxycarbonyl” is meant —C(O)—OR, where R is an optionally substituted aliphatic group, as described herein. In particular embodiments, the alkoxycarbonyl group is —C(O)—OAk, in which Ak is an alkyl group, as defined herein. The alkoxycarbonyl group can be substituted or unsubstituted. For example, the alkoxycarbonyl group can be substituted with one or more substitution groups, as described herein for alkyl. Exemplary unsubstituted alkoxycarbonyl groups include C₂₋₃, C₂₋₆, C₂₋₇, C₂₋₁₂, C₂₋₁₆, C₂₋₁₈, C₂₋₂₀, or C₂₋₂₄ alkoxycarbonyl groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl (Hx), heptyl (Hp), octyl (Oc), nonyl (Nn), decyl (De), dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₄₋₈ aryl-C₁₋₆ alkyl (e.g., -L-R, in which L is C₁₋₆ alkyl and R is C₄₋₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₄₋₈ aryl-C₁₋₆ alkyl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₄₋₈ aryl-C₁₋₆ alkyl (e.g., -L-R, in which L is C₁₋₆ alkyl and R is C₄₋₁₈ aryl); (25) -SO₂NRT¹R², where each of R¹ and R² is, independently, selected from the group consisting of (a) hydrogen, (b) C₁₋₆ alkyl, (c) C₄₋₁₈ aryl, and (d) C₄₋₈ aryl-C₁₋₆ alkyl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₈ aryl, (g) C₄₋₈ aryl-C₁₋₆ alkyl (e.g., -L-R, in which L is C₁₋₆ alkyl and R is C₄₋₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene,” “alkenylene,” or “alkynylene” is meant a multivalent (e.g., bivalent) form of an alkyl, alkenyl, or alkynyl group, respectively, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. In other embodiments, the alkylene group is a C₂₋₃, C₂₋₆, C₂₋₁₂, C₂₋₁₆, C₂₋₁₈, C₂₋₂₀, or C₂₋₂₄ alkenylene or alkynylene group. The alkylene, alkenylene, or alkynylene group can be branched or unbranched. The alkylene, alkenylene, or alkynylene group can also be substituted or unsubstituted. For example, the alkylene, alkenylene, or alkynylene group can be substituted with one or more substitution groups, as described herein for alkyl.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfinylalkyl” is meant an alkyl group, as defined herein, substituted by an alkylsulfinyl group. In some embodiments, the unsubstituted alkylsulfinylalkyl group is a C₂₋₁₂ or C₂₋₂₄ alkylsulfinylalkyl group (e.g., C₁₋₆ alkylsulfinyl-C₁₋₆ alkyl or C₁₋₁₂ alkylsulfinyl-C₁₋₁₂ alkyl). In other embodiments, the alkylsulfinylalkyl group is -L-S(O)—R, in which each of L and R is, independently, an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkylsulfonylalkyl” is meant an alkyl group, as defined herein, substituted by an alkylsulfonyl group. In some embodiments, the unsubstituted alkylsulfonylalkyl group is a C₂₋₁₂ or C₂₋₂₄ alkylsulfonylalkyl group (e.g., C₁₋₆ alkylsulfonyl-C₁₋₆ alkyl or C₁₋₁₂ alkylsulfonyl-C₁₋₁₂ alkyl). In other embodiments, the alkylsulfonylalkyl group is -L-SO₂—R, in which each of L and R is, independently, an alkyl group, as defined herein.

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An exemplary alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “ambient temperature” is meant a temperature ranging from 16° C. to 26° C., such as from 19° C. to 25° C. or from 20° C. to 25° C.

By “amide” is mean —C(O)NR¹R² or —NHCOR¹, where each of R¹ and R² is, independently, selected from hydrogen, aliphatic, heteroaliphatic, aromatic, as defined herein, or any combination thereof, or where R¹ and R², taken together with the nitrogen atom to which each are attached, can form a heterocyclyl group, as defined herein.

By “amino” is meant —NR¹R², where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amino group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, or aromatic, as defined herein, or any combination thereof, or R¹ and R², taken together with the nitrogen atom to which each are attached, can form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, or aromatic, as defined herein, or any combination thereof, or R¹ and R², taken together with the nitrogen atom to which each are attached, can form a heterocyclyl group, as defined herein; and each of R³ and R⁴ is, independently, H or alkyl, as defined herein.

By “aminooxy” is meant an oxy group, as defined herein, substituted by an amino group, as defined herein. In some embodiments, the aminooxy group is —O—NR¹R², in which each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or R¹ and R², taken together with the nitrogen atom to which each are attached, can form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system. An aromatic group is unsubstituted or substituted, e.g., by a functional group described herein. For example, the aromatic group can be substituted with one or more substitution groups, as described herein for alkyl and/or aryl.

By “aromatic-carbonyl” is meant an aromatic group that is or can be coupled to a compound disclosed herein, wherein the aromatic group is or becomes coupled through a carbonyl group (—C(O)—). In some embodiments, the aromatic-carbonyl group is —C(O)—R, in which R is an optionally substituted aromatic group, as defined herein.

By “aromatic-carbonyloxy” is meant an aromatic group that is or can be coupled to a compound disclosed herein, wherein the aromatic group is or becomes coupled through a carbonyloxy group (—OC(O)—). In some embodiments, the aromatic-carbonyloxy group is —OC(O)—R, in which R is an optionally substituted aromatic group, as defined herein.

By “aromatic-oxy” is meant an aromatic group that is or can be coupled to a compound disclosed herein, wherein the aromatic group is or becomes coupled through an oxy group (—O—). In some embodiments, the aromatic-oxy group is —O—R, in which R is an optionally substituted aromatic group, as defined herein.

By “aromatic-oxycarbonyl” is meant an aromatic group that is or can be coupled to a compound disclosed herein, wherein the aromatic group is or becomes coupled through an oxycarbonyl group (—C(O)O—). In some embodiments, the aromatic-carbonyl group is —C(O)O—R, in which R is an optionally substituted aromatic group, as defined herein.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Exemplary aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amino (e.g., —NR¹R², where each of R¹ and R² is, independently, selected from hydrogen, aliphatic, heteroaliphatic, haloaliphatic, haloheteroaliphatic, aromatic, as defined herein, or any combination thereof; or R¹ and R², taken together with the nitrogen atom to which each are attached, can form a heterocyclyl group, as defined herein); (11) C₁₋₆ aminoalkyl (e.g., —Li—NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein; and each of R³ and R⁴ is, independently, H or C₁₋₆ alkyl); (12) heteroaryl; (13) C₄₋₁₈ aryl-C₁₋₆ alkyl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₃₋₈ cycloalkyl-C₁₋₆ alkyl (e.g., -L-R, in which L is C₁₋₆ alkyl and R is C₃₋₈ cycloalkyl); (22) halo; (23) C₁₋₆ haloalkyl (e.g., —Li—X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., —Li—OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkyl (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₈ aryl, and (d) C₄₋₈ aryl-C₁₋₆ alkyl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₄₋₈ aryl-C₁₋₆ alkyl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₈ aryl, and (c) C₄₋₁₈ aryl-C₁₋₆ alkyl (e.g., -L-R, in which L is C₁₋₆ alkyl and R is C₄₋₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₈ aryl, and (d) C₄₋₁₈ aryl-C₁₋₆ alkyl (e.g., -L-R, in which L is C₁₋₆ alkyl and R is C₄₋₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₄₋₁₈ aryl-C₁₋₆ alkyl (e.g., -L-R, in which L is C₁₋₆ alkyl and R is C₄₋₈ aryl), (h) C₃₋₈ cycloalkyl, and (i) C₃₋₈ cycloalkyl-C₁₋₆ alkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “aryl-alkyl,” “aryl-alkenyl,” and “aryl-alkynyl” is meant an aryl group, as defined herein, that is or can be coupled (or attached) to the parent molecular group through an alkyl, alkenyl, or alkynyl group, respectively, as defined herein. The aryl-alkyl, aryl-alkenyl, and/or aryl-alkynyl group can be substituted or unsubstituted. For example, the aryl-alkyl, aryl-alkenyl, and/or aryl-alkynyl group can be substituted with one or more substitution groups, as described herein for aryl and/or alkyl. Exemplary unsubstituted aryl-alkyl groups are of from 7 to 16 carbons (C₇₋₁₆ aryl-alkyl), as well as those having an aryl group with 4 to 18 carbons and an alkyl group with 1 to 6 carbons (i.e., C₄₋₈ aryl-C₁₋₆ alkyl). Exemplary unsubstituted aryl-alkenyl groups are of from 7 to 16 carbons (C₇₋₁₆ aryl-alkenyl), as well as those having an aryl group with 4 to 18 carbons and an alkenyl group with 2 to 6 carbons (i.e., C₄₋₈ aryl-C₂₋₆ alkenyl). Exemplary unsubstituted aryl-alkynyl groups are of from 7 to 16 carbons (C₇₋₁₆ aryl-alkynyl), as well as those having an aryl group with 4 to 18 carbons and an alkynyl group with 2 to 6 carbons (i.e., C₄₋₁₈ aryl-C₂₋₆ alkynyl). In some embodiments, the aryl-alkyl group is -L-R, in which L is an alkyl group or an alkylene group, as defined herein, and R is an aryl group, as defined herein. In some embodiments, the aryl-alkenyl group is -L-R, in which L is an alkenyl group or an alkenylene group, as defined herein, and R is an aryl group, as defined herein. In some embodiments, the aryl-alkynyl group is -L-R, in which L is an alkynyl group or an alkynylene group, as defined herein, and R is an aryl group, as defined herein.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted.

For example, the arylene group can be substituted with one or more substitution groups, as described herein for aryl.

By “arylalkoxy” is meant an aryl-alkyl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group. In other embodiments, R is an aryl group that is optionally substituted with alkyl, alkanoyl, amino, hydroxyl, and the like.

By “aryloxycarbonyl” is meant an aryloxy group, as defined herein, that is attached to the parent molecular group through a carbonyl group. In some embodiments, an unsubstituted aryloxycarbonyl group is a C₅₋₁₉ aryloxycarbonyl group. In other embodiments, the aryloxycarbonyl group is —C(O)O—R, in which R is an aryl group, as defined herein.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “aryloyloxy” is meant an aryloyl group, as defined herein, that is attached to the parent molecular group through an oxy group. In some embodiments, an unsubstituted aryloyloxy group is a C₅₋₁₉ aryloyloxy group. In other embodiments, the aryloyloxy group is —OC(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein.

By “azo” is meant an —N═N— group.

By “carbamoyl” is meant an amino group attached to the parent molecular group through a carbonyl group, as defined herein. In some embodiments, the carbamoyl is —C(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where R¹ and R², taken together with the nitrogen atom to which each are attached, can form a heterocyclyl group, as defined herein.

By “carbamoyloxy” is meant a carbamoyl group, as defined herein, attached to the parent molecular group through n oxy group, as defined herein. In some embodiments, the carbamoyl is —OC(O)NR¹R² group, where each of R¹ and R² is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where R¹ and R², taken together with the nitrogen atom to which each are attached, can form a heterocyclyl group, as defined herein.

By “carbonimidoyl” is meant a —C(NR)— group. In some embodiments, R is selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof.

By “carbonyl” is meant a —C(O)— group, which can also be represented as >C═O.

By “carboxyl” is meant a —CO₂H group or an anion thereof.

By “catalyst” is meant a compound, usually present in small amounts relative to reactants, capable of catalyzing a synthetic reaction, as would be readily understood by a person of ordinary skill in the art. In some embodiments, catalysts may include transition metal coordination complex.

By “cyanato” is meant a —OCN group.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant a —O-L-R group, in which L is an alkyl group or an alkylene group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl], and the like. The cycloalkyl group can also be substituted or unsubstituted. For example, the cycloalkyl group can be substituted with one or more groups including those described herein for alkyl. Further, cycloalkyl may include one or more double bonds and/or triple bonds.

By “cycloheteroaliphatic” is meant a heteroaliphatic group, as defined herein, that is cyclic.

By “disilanyl” is meant a group containing an Si—Si bond. In some embodiments, the disilanyl group is a —SiR^{S1}R^{S2}—SiR^{S3}R^{S4}R^{S5} or —SiR^{S1}R^{S2}—SiR^{S3}R^{S4}— group, in which each of R^{S1}, R^{S2}, R^{S3}, R^{S4}, and R^{S5} is, independently, H, optionally substituted aliphatic, optionally substituted heteroaliphatic, optionally substituted aromatic, optionally substituted heteroaromatic, or optionally substituted amino.

By “disulfide” is meant —SSR, where R is selected from hydrogen, aliphatic, heteroaliphatic, haloaliphatic, haloheteroaliphatic, aromatic, as defined herein, or any combination thereof.

By “electron-donating group” is meant a functional group capable of donating at least a portion of its electron density into the ring to which it is directly attached, such as by resonance.

By “electron-withdrawing group” is meant a functional group capable of accepting electron density from the ring to which it is directly attached, such as by inductive electron withdrawal.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaliphatic group is unsubstituted or substituted, e.g., by a functional group described herein. For example, the heteroaliphatic group can be substituted with one or more substitution groups, as described herein for alkyl.

By “heteroaliphatic-carbonyl” is meant a heteroaliphatic group that is or can be coupled to a compound disclosed herein, wherein the heteroaliphatic group is or becomes coupled through a carbonyl group (—C(O)—). In some embodiments, the heteroaliphatic-carbonyl group is —C(O)—R, in which R is an optionally substituted heteroaliphatic group, as defined herein.

By “heteroaliphatic-carbonyloxy” is meant a heteroaliphatic group that is or can be coupled to a compound disclosed herein, wherein the heteroaliphatic group is or becomes coupled through a carbonyloxy group (—OC(O)—). In some embodiments, the heteroaliphatic-carbonyloxy group is —OC(O)—R, in which R is an optionally substituted heteroaliphatic group, as defined herein.

By “heteroaliphatic-oxy” is meant a heteroaliphatic group that is or can be coupled to a compound disclosed herein, wherein the heteroaliphatic group is or becomes coupled through an oxy group (—C(O)—). In some embodiments, the heteroaliphatic-oxy group is —O—R, in which R is an optionally substituted heteroaliphatic group, as defined herein.

By “heteroaliphatic-oxycarbonyl” is meant a heteroaliphatic group that is or can be coupled to a compound disclosed herein, wherein the heteroaliphatic group is or becomes coupled through an oxycarbonyl group (—C(O)O—). In some embodiments, the heteroaliphatic-oxycarbonyl group is —C(O)O—R, in which R is an optionally substituted heteroaliphatic group, as defined herein.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkylene,” “heteroalkenylene,” and “heteroalkynylene” is meant a multivalent (e.g., bivalent) form of a heteroalkyl, heteroalkenyl, or heteroalkynyl group, respectively, as described herein.

By “heteroaromatic” is meant an aromatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group. A heteroaromatic group is unsubstituted or substituted, e.g., by a functional group described herein. For example, the heteroaromatic group can be substituted with one or more substitution groups, as described herein for alkyl and/or aryl.

By “heteroaromatic-carbonyl” is meant a heteroaromatic group that is or can be coupled to a compound disclosed herein, wherein the heteroaromatic group is or becomes coupled through a carbonyl group (—C(O)—). In some embodiments, the heteroaromatic-carbonyl group is —C(O)—R, in which R is an optionally substituted heteroaromatic group, as defined herein.

By “heteroaromatic-carbonyloxy” is meant a heteroaromatic group that is or can be coupled to a compound disclosed herein, wherein the heteroaromatic group is or becomes coupled through a carbonyloxy group (—OC(O)—). In some embodiments, the heteroaromatic-carbonyloxy group is —OC(O)—R, in which R is an optionally substituted heteroaromatic group, as defined herein.

By “heteroaromatic-oxy” is meant a heteroaromatic group that is or can be coupled to a compound disclosed herein, wherein the heteroaromatic group is or becomes coupled through an oxy group (—O—). In some embodiments, the heteroaromatic-oxy group is —O—R, in which R is an optionally substituted heteroaromatic group, as defined herein.

By “heteroaromatic-oxycarbonyl” is meant a heteroaromatic group that is or can be coupled to a compound disclosed herein, wherein the heteroaromatic group is or becomes coupled through an oxycarbonyl group (—C(O)O—). In some embodiments, the heteroaromatic-carbonyl group is —C(O)O—R, in which R is an optionally substituted heteroaromatic group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An exemplary heteroaryl includes a subset of heterocyclyl groups, as defined herein, which are aromatic, i.e., they contain 4n+2 pi electrons within the mono- or multicyclic ring system.

By “heteroarylene” is meant a multivalent (e.g., bivalent) form of a heteroaryl group, as described herein.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydrazino” is meant —NR¹—NR²R³, where each of R¹, R², and R³ is, independently, selected from hydrogen, optionally substituted aliphatic, optionally substituted heteroaliphatic, optionally substituted aromatic, optionally substituted heteroaromatic, optionally substituted silyl, or optionally substituted silyloxy, as defined herein, or any combination thereof, or where a combination of R¹ and R² or a combination of R² and R³, taken together with the nitrogen atom to which each are attached, can form a heterocyclyl group, as defined herein. In some embodiments, each of R¹, R², or R³ is, independently, H, optionally substituted alkyl, optionally substituted aryl, optionally substituted alkyl-aryl, or optionally substituted aryl-alkyl. In particular embodiments, R² and R³ can be taken together, with the nitrogen atom to which each is attached, to form an optionally substituted heterocyclyl.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “imidoyl” is meant a moiety including a carbonimidoyl group. In some embodiments, the imidoyl group is C(NR¹)R², in which each of R¹ and R² is, independently, selected from hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, optionally substituted silyloxy, as defined herein, or any combination thereof. In other embodiments, the imidoyl group is —C(NR¹)H, —C(NR¹)R^{Ak}, or —C(NR^{N1})R^{Ar} in which R¹ is hydrogen, optionally substituted aliphatic, optionally substituted heteroaliphatic, optionally substituted aromatic, optionally substituted heteroaromatic, optionally substituted silyl, optionally substituted alkyl, optionally substituted aryl, optionally substituted alkyl-aryl, or optionally substituted aryl-alkyl, or optionally substituted silyloxy; R^{Ak} is an optionally substituted alkyl or an optionally substituted aliphatic; and R^{Ar} is an optionally substituted aryl or an optionally substituted aromatic.

By “imino” is meant a —NR— group. In some embodiments, R is selected from hydrogen, optionally substituted aliphatic, optionally substituted heteroaliphatic, optionally substituted aromatic, or optionally substituted heteroaromatic. In particular embodiments, R is H, optionally substituted alkyl, optionally substituted alkoxy, optionally substituted aryl, optionally substituted aryloxy, optionally substituted alkyl-aryl, or optionally substituted aryl-alkyl.

By “isocyanato” is meant a —NCO group.

By “isocyano” is meant a —NC group.

By “ketone” is meant —C(O)R or a compound including such a group, where R is selected from aliphatic, heteroaliphatic, aromatic, as defined herein, or any combination thereof. An example of a ketone can include R¹C(O)R, in which each of R and R¹ is, independently, selected from aliphatic, haloaliphatic, haloheteroaliphatic, heteroaliphatic, aromatic, aliphatic-aromatic, heteroaliphatic-aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Exemplary perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S. M. et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amino cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²— group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR²)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR²)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl

By “sulfinyl” is meant an —S(O)— group.

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkyl” is meant an alkyl group, as defined herein, attached to the parent molecular group through a sulfur atom. Exemplary unsubstituted thioalkyl groups include C₁₋₆ thioalkyl. In some embodiments, the thioalkyl group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

As used herein, the term “about” means +/−10% of any recited value. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

Other features and advantages of the disclosed embodiments will be apparent from the following description and the claims.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for processing substrates, the method comprising:
providing a semiconductor substrate having an exposed surface to a process chamber;
performing a pre-treatment on the semiconductor substrate by either (1) heating the semiconductor substrate to a first temperature and/or (2) exposing the semiconductor substrate to a nitrogen-containing plasma;
introducing flow of a halosilane gas to the process chamber using a dose time;
after stopping flow of the halosilane gas, purging the process chamber for a first purge time;
introducing flow of a first nitrogen-containing gas to the process chamber using a conversion time to form silicon nitride by thermal atomic layer deposition; and
after stopping flow of the first nitrogen-containing gas, purging the process chamber for a second purge time.

2. A method for processing substrates, the method comprising:
providing a semiconductor substrate having an exposed surface to a process chamber;
heating the semiconductor substrate to a first temperature;
performing a pre-treatment on the semiconductor substrate by exposing the semiconductor substrate to a nitrogen-containing plasma;
after performing the pre-treatment, heating the semiconductor substrate to a second temperature;
after heating the semiconductor substrate to the second temperature, introducing flow of a halosilane gas to the process chamber in a plasma-free environment using a dose time;
after stopping flow of the halosilane gas, purging the process chamber for a first purge time;
introducing flow of a first nitrogen-containing gas to the process chamber using a conversion time to form silicon nitride in a plasma-free environment; and
after stopping flow of the first nitrogen-containing gas, purging the process chamber for a second purge time.

3. The method of claim 1, further comprising wherein the exposed surface comprises silicon oxide.

4. The method of claim 1, wherein the nitrogen-containing plasma is formed by igniting a second nitrogen-containing gas.

5. The method of claim 2, wherein the first temperature and the second temperature are the same.

6. The method of claim 1, wherein the halosilane gas comprises chlorine.

7. A method for processing substrates, the method comprising:
providing a semiconductor substrate having an exposed surface to a process chamber;
exposing the exposed surface to a nitrogen-containing plasma;
introducing flow of a silicon-containing gas to the process chamber using a dose time;
after stopping flow of the silicon-containing gas, purging the process chamber for a first purge time;
introducing flow of a first nitrogen-containing gas to the process chamber using a conversion time to form silicon nitride by thermal atomic layer deposition; and
after stopping flow of the first nitrogen-containing gas, purging the process chamber for a second purge time,
wherein a ratio of the dose time to conversion time is about 1:1 to about 10:4.

8. (canceled)

9. (canceled)

10. (canceled)

11. The method of claim 4, wherein the second nitrogen-containing gas is selected from the group consisting of nitrogen, ammonia, nitrous oxide, and combinations thereof.

12. The method of claim 2, wherein the first temperature is less than about 800° C.

13. The method of claim 2, wherein the halosilane gas comprises chlorine.

14. The method of claim 7, wherein the silicon nitride has an atomic ratio of silicon to nitrogen of at least about 0.69.

15. The method of claim 7, wherein the silicon nitride has an atomic ratio of silicon to nitrogen of at least about 1.

16. The method of claim 7, wherein the silicon-containing gas comprises chlorine.

17. The method of claim 7, wherein the silicon-containing gas is a halosilane.

18. The method of claim 7, wherein the exposed surface comprises silicon.

19. The method of claim 18, wherein the exposed surface further comprises oxygen.
